(19) United States
(12) Patent Application Publication
(10) Pub. No.: US 2025/0107450 A1
(43) Pub. Date: Mar. 27, 2025

(54) ACTUATOR MODULE WITH A HERMETICALLY SEALED HOUSING

(71) Applicant: VERMES MICRODISPENSING GMBH, Holzkirchen (DE)

(72) Inventor: Wolfram HELLMICH, Baldham (DE)

(73) Assignee: VERMES MICRODISPENSING GMBH, Holzkirchen (DE)

(21) Appl. No.: 18/832,276

(22) PCT Filed: Feb. 14, 2023
(86) PCT No.: PCT/EP2023/053593

§ 371 Date: Jul. 23, 2024

(30) Foreign Application Priority Data
Feb. 25, 2022 (DE) 102022104624.9
Oct. 25, 2022 (DE) 102022128265.1

(51) Int. Cl. H10N 30/88; H10N 30/02

(52) U.S. Cl. CPC H10N 30/88; H10N 30/02

(57) ABSTRACT

The invention relates to an actuator module (1) with a hermetically sealed housing (3) with at least one piezo actuator (2) arranged in the housing (3) and with electrical terminals (21, 22) at least for the piezo actuator (2). The terminals (21, 22) are fed through a housing wall (31, 32, 34), wherein a housing interior space (30) between the piezo actuator (2) and the housing wall (31, 32, 34) includes a potting compound (4), which electrically insulates the housing wall (31, 32, 34) from the piezo actuator (2). The potting compound (4) is a solid and comprises at least one particulate, heat-conducting, dielectric auxiliary substance (40), wherein the auxiliary substance (40) is arranged in the potting compound (4) so that a heat dissipation from the piezo actuator (2) to the housing wall (31, 32, 34) takes place during operation via the potting compound (4), in particular via the auxiliary substance (40).

The invention relates to an actuator module with a hermetically sealed housing with at least one piezo actuator arranged in the housing and with electrical terminals at least for the piezo actuator, a metering system with such an actuator module, a method for producing such an actuator module, a use of such an actuator module in a metering system and a hermetically sealed housing.

Piezoceramic multilayer actuators or piezo actuators, in short, consist of a plurality of stacked thin layers of a piezoelectric material, e.g., lead zirconate titanate. In the case of such multilayer piezo actuators (also referred to as “multilayer elements” or “piezo stack”), a cascading takes place in that several thin piezo elements with inner electrodes lying therebetween are joined together. The inner electrodes are alternatingly fed to a surface of the piezo actuator, wherein two outer electrodes connect the respective inner electrodes. The inner electrodes are electrically connected in parallel and are combined to form two groups, which form the connection poles of the piezo actuator. When applying an electrical voltage to the connection poles, said electrical voltage is transferred to the inner electrodes in parallel and effects an electrical field via this in the layers of the piezoelectric material. The sum of the mechanical deformations of the individual layers of the piezoelectric material results in the usable expansion and/or force of the piezo actuator.

Piezo actuators are used in different technical fields, e.g., in actuating and positioning drives or in metering systems for systematically metering liquid to viscous metering substances, in particular in so-called jet valves. Particular advantages of piezo actuators are, for example, that they have a large stiffness and compressive strength, provide for a high position resolution, display a quick response behavior and effect high accelerations and generally operate without wear.

Regardless of these advantages, the reliability of piezo actuators has often turned out to be insufficient in the past. Due to a high electrical field strength, which is applied to a surface of the piezo actuator during operation, polar molecules, e.g., water molecules, are attracted from the ambient air of the actuator. The accumulation of water molecules leads to an increased conductivity on the surface of the piezo actuator and to increasing leakage current. As a result, a short-circuit can occur in the layers of the piezoelectric material, which has a disadvantageous effect on the service life of the piezo actuator.

Even though piezo actuators are known, in the case of which the piezoelectric material is coated, e.g., with a ceramic coating or with glass, microcracks often form during operation of the piezo actuator, wherein water molecules can pass through the coating. Piezo actuators are further known, which are arranged in a metal sleeve or in a metal housing. In the case of such piezo actuators, there is often the problem that small quantities of water molecules in the housing, e.g., as a result of the production, can already be sufficient in order to trigger the described disadvantageous effect.

There are also piezo actuators, which are tightly enclosed in a metal housing, wherein, e.g., a water-absorbent medium can be arranged in the housing, for example a medium, which chemically converts and/or binds water molecules. It can be a disadvantage of such piezo actuators that the production thereof is comparatively complex due to a complex production method and the used chemicals.

A further disadvantage of piezo actuators, which are tightly enclosed in a metal housing—with or without water-absorbent medium—can result from the fact that a heat dissipation from the surface of the piezo actuator is limited during operation of the piezo actuator due to the metal housing and/or a (water-absorbent) medium in the housing. The temperature of a piezo actuator can have an effect on the geometry of the piezo actuator, in particular on the longitudinal extension thereof in an (unswitched) rest state.

As a result of a thermally induced expansion, in particular due to an insufficient heat dissipation from the piezo actuator during operation, the longitudinal extension of the piezo actuator effected as a result of a wiring of the piezo actuator and/or a generated force and/or a position of the piezo actuator within a machine can deviate from a specific target value. Due to the fact that a particularly high precision is required in many applications during operation of the piezo actuator, a temperature-induced length change of a piezo actuator is to be avoided, if possible.

Known piezo actuators with a tightly sealed metal housing and/or with specific, e.g., water-absorbent medium in the housing can thus only be used to a limited extent in many technical fields. In particular in the case of the above-mentioned jet valves, which currently typically operate at high clock frequencies of up to 1 kHz, wherein a correspondingly large lost heat develops in the piezo actuator, an actuator module is desirable, which provides for a sufficient heat dissipation from the surface of the piezo actuator and simultaneously provides for an effective protection of the piezo actuator against damaging environmental conditions for a reliable operation.

It is the object of the present invention to provide an actuator module with a hermetically sealed housing, a metering system with such an actuator module as well as a method for producing an actuator module and a housing, by means of which the above-described disadvantages can be avoided or at least reduced.

This object is solved by means of an actuator module according to patent claim 1 and a production method according to patent claim 7 as well as by means of a metering system according to patent claim 14 and by means of a housing according to patent claim 15 as well as by means of a use of an actuator module according to patent claim 16.

An actuator module according to the invention has a hermetically tightly, in particular an inherently tightly, sealed housing. At least one piezo actuator is arranged in an interior of the housing. The piezo actuator can in particular be a piezoceramic multilayer actuator. The actuator module has at least two electrical terminals at least for the piezo actuator. The electrical terminals are fed through a housing wall of the housing, in particular in a hermetically tight and electrically insulated manner.

In the context of the invention, the term “hermetically” sealed is understood so that the housing is formed so that no substances can pass through the housing or no substances can pass through the sealed housing, respectively. The housing is “hermetically” sealed so that no solids and/or no liquids and/or no gases can enter into the housing from the outside, during operation of the actuator module. The housing preferably forms an “absolutely tight” enclosure or inclusion, respectively, of the piezo actuator with respect to an environment of the housing. An “absolutely tight” housing is understood such that in particular an exchange of air and/or water molecules is prevented via the housing. The housing can accordingly be “absolutely tight” for a certain operating time at least (relatively) with regard to air and/or water molecules, in particular in order to prevent a long-term diffusion of water molecules through the materials of the housing during operation. The tightness of the housing can be analyzed, e.g., via a helium leak test. The housing can in particular be a deep-drawn housing, as will be described later.

According to the invention, a potting compound, which electrically insulates the housing wall, in particular during operation of the piezo actuator, with respect to the piezo actuator, is arranged in a housing interior space in the interior of the housing between the piezo actuator and the housing wall.

The potting compound is a solid, in particular an elastic solid, and comprises at least one particulate, heat-conducting and dielectric auxiliary substance. In particular, the auxiliary substance itself is a dielectric. The auxiliary substance is formed in a particulate manner, i.e., the auxiliary substance is present as solid in the potting compound. The auxiliary substance can also be referred to as functional substance.

According to the invention, the auxiliary substance is arranged in the potting compound in the housing so that a heat dissipation from the piezo actuator to the housing wall takes place during operation of the actuator module via the potting compound, in particular via the auxiliary substance in the potting compound. The auxiliary substance is preferably arranged in the potting compound so that a heat dissipation from a surface of the piezo actuator takes place essentially evenly along an entire longitudinal extension of the piezo actuator, in particular in a lateral direction, during operation of the actuator module. The heat dissipated from the piezo actuator can preferably be largely transferred to a housing jacket of a housing wall, as will be described later. The heat dissipated from the piezo actuator can in particular be lost heat, which is created during operation of the piezo actuator.

The reliability of a piezo actuator can advantageously be improved by means of the actuator module according to the invention because the piezo actuator is effectively protected against damaging environmental influences via the hermetically sealed housing, in particular against (air) moisture. A particularly efficient heat dissipation from the piezo actuator can furthermore take place via the combination of a solid, elastic potting compound with a heat-conducting, dielectric auxiliary substance arranged therein according to the invention, wherein the piezo actuator can be reliably protected against an overheating. On the one hand, this can have an advantageous effect on the service life of the piezo actuator itself, so that the latter or the actuator module, respectively, has to be replaced less frequently. On the other hand, a particularly high metering precision can be attained by means of the actuator module in the case of metering systems because a thermally induced expansion of the piezo actuator is largely prevented, wherein an efficiency of a metering system can also be improved because the piezo actuator is protected against an overheating even during continuous operation, so that interruptions of the metering operation due to a critical piezo actuator temperature can be avoided.

The actuator module according to the invention is further advantageously also suitable for applications, in the case of which particularly high clock frequencies of a piezo actuator are required because a particularly efficient dissipation of lost heat from a piezo actuator surface to a housing wall and, via this, an output of the heat into the environment is possible via the potting compound and the added auxiliary substance. The actuator module can thus advantageously be used in jet valves with a very high clock frequency of, e.g., up to 2 kHz, which corresponds to at least a doubling of the clock frequency compared to conventional jet valves and which is not readily possible with known actuator modules. The actuator module could furthermore also be operated successfully in jet valves, which operate with clock frequencies of 3 kHz or 4 KHz.

A method according to the invention for producing an actuator module, preferably of an actuator module according to the invention, with a hermetically sealed housing and at least one piezo actuator arranged in the housing comprises at least the following steps:

In one step, a hermetically sealable housing is provided, wherein the housing has electrical terminals at least for one piezo actuator. In the sealed state of the housing, the terminals are fed through a housing wall of the housing, in particular in a hermetically tight and electrically insulated manner. The provision of the housing can include the feedthrough of the electrical terminals through the housing wall. It is also possible, however, that a housing with the fed-through electrical terminals is inserted in the method. The housing can in particular be a deep-drawn housing.

In a further step, at least one piezo actuator is introduced into a housing interior space in the interior of the housing. Prior to the introduction of the piezo actuator into the housing, the electrical terminals of the housing are preferably brought into active contact with assigned connection points or connection poles, respectively of the piezo actuator. For example, the electrical terminals can be fed through a housing cover, wherein the electrical terminals are connected to the connection poles of the piezo actuator and/or wherein the piezo actuator is fixed to the housing cover prior to the introduction of the piezo actuator into the housing interior space.

In an optional step, at least a portion of the piezo actuator, in particular at least a portion of a surface of the piezo actuator, can be cleaned by means of a plasma. Essentially the entire surface of the piezo actuator, which faces the housing wall, can preferably be cleaned by means of plasma cleaning. An (outer) surface of the piezoceramic material of the piezo actuator and/or the connector poles of the piezo actuator can preferably be cleaned by means of plasma, in particular a surface of the piezo actuator between the connector poles.

Alternatively or additionally, at least a portion of an inner side of the housing wall can optionally be cleaned by means of a plasma. The inner side of the housing wall is the region of the housing wall, which faces the housing interior space, in particular the piezo actuator in the housing. The (interior) housing wall facing the housing interior space can accordingly be cleaned by means of plasma cleaning at least in sections. Essentially the entire housing wall directed at the housing interior space, in particular essentially the entire inner side of the housing wall, can preferably be cleaned by means of a plasma.

In a further step, a potting compound is provided, which, preferably in the hardened state, electrically insulates the housing wall with respect to the piezo actuator.

In a further step, the, preferably free-flowing, potting compound is introduced into the housing interior space between the piezo actuator and the housing wall. The potting compound can preferably be introduced into the housing interior space via a filling opening in the housing, in particular in a housing cover.

In particular after a hardening or curing, respectively, in the housing interior space in the housing, the potting compound is a solid, preferably an elastic solid and comprises at least one particulate, heat-conducting and dielectric auxiliary substance. The auxiliary substance is arranged in the potting compound so that a heat dissipation from the piezo actuator, in particular from a piezo actuator surface, to the housing wall takes place during operation of the actuator module via the potting compound, in particular via the auxiliary substance in the potting compound.

In a further step, the housing is hermetically sealed in order to form the actuator module. For this purpose, the filling opening can preferably be closed by pressing in a pressing ball, which has a larger diameter than the filling opening.

It should be pointed out that the method steps do not mandatorily have to be performed in the described order. It would also be possible that two method steps are combined into one step or are performed essentially simultaneously.

Advantageously, actuator modules, which are particularly suitable for use in metering systems, such as, e.g., in jet valves, can be produced by means of the method. Such actuator modules for metering systems have to often meet particularly strict quality requirements, in particular with regard to a shielding of the piezo actuator against moisture and a piezo actuator temperature during operation, wherein these requirements can be met by means of the production method according to the invention and the actuator modules, which can be obtained thereby.

A metering system according to the invention for a metering substance comprises a nozzle for outputting metering substance, a supply channel for metering substance to the nozzle, a preferably movably mounted ejection element and an actuator module according to the invention, which is coupled to the ejection element and/or to the nozzle, with a hermetically sealed housing and at least one piezo actuator arranged in the housing. The metering system can comprise further components, as will be described later.

The actuator module according to the invention can advantageously be used successfully in a metering system, in particular in a jet valve, as has been described above. A clock frequency for the metering substance output can be increased significantly compared to known metering systems with conventional encapsulated piezo actuators, in particular by using the actuator module.

The invention furthermore relates to a hermetically tightly sealed housing with at least one component arranged in the housing, preferably a piezo actuator. The housing comprises at least two electrical terminals at least for the component, in particular for controlling the piezo actuator. The terminals are fed through a housing wall of the housing, in particular in a hermetically tight and electrically insulated manner. The housing has a housing base body, which is formed in one piece, and a housing cover connected thereto, in particular in a hermetically tight manner.

According to the invention, the housing base body can be obtained by means of deep-drawing, in particular by means of deep-drawing of a sheet metal blank. This means that the housing base body is a deep-drawn part. The housing base body is formed integrally or in one piece, respectively, and comprises a, preferably tubular, housing jacket and a housing bottom, wherein the housing bottom closes or delimits, respectively, the housing jacket on an (end) side. Depending on the design of the housing and/or arrangement of the component, e.g., of the piezo actuator, the housing bottom can generally also be referred to as housing cover. The housing base body according to the invention is accordingly defined in that the housing base body is formed in one piece and comprises at least one housing jacket and a one-sided limitation of the housing jacket, which is firmly connected thereto, e.g., similarly to a deep-drawn pot. Without being limited thereto, it is assumed in the description that the housing base body comprises a housing jacket and a housing bottom, which is connected thereto in one piece.

In the case of the housing, a mass of the housing bottom produced by means of deep-drawing can advantageously be reduced significantly compared to conventional housings with a separate housing bottom, which is subsequently welded, e.g., to a housing jacket. Due to the fact that the housing bottom, which can be actively moved by the piezo actuator, has a comparatively low mass, the effective stroke of the piezo actuator can be increased significantly compared to conventionally encapsulated piezo actuators. Due to the fact that in the case of the housing, only one element is to still be connected to the housing base body, e.g., a housing cover, the production of the housing is less complex in view of a hermetic tightness, which is to be attained.

Due to the low moved mass of the housing bottom, the housing is also suitable for metering systems with particularly high clock frequencies, in particular jet valves. Accordingly, the deep-drawn housing can particularly preferably be used as part of an actuator module according to the invention because the advantageous effects of the housing can thus be supplemented synergistically with the advantages of the particular actuator module, in particular in the case of high clock frequencies.

The invention furthermore relates to a use of an actuator module with a hermetically sealed housing and at least one piezo actuator arranged in the housing, in particular an actuator module according to the invention, in a metering system with at least one supply channel for metering substance, a nozzle for outputting metering substance and a preferably movably mounted ejection element, wherein the actuator module cooperates with or is coupled to, respectively, the ejection element and/or the nozzle during operation in order to output metering substance.

Further, particularly advantageous designs and further developments of the invention follow from the dependent claims as well as from the following description, wherein the independent claims of one claim category can also be further developed analogously to the dependent claims and exemplary embodiments of a different claim category and individual features of different exemplary embodiments or variations, respectively, can also be combined to form new exemplary embodiments or variations, respectively.

The housing is formed so that the entire piezo actuator is arranged completely in the housing. The piezo actuator is in particular encapsulated in a hermetically tight manner in the housing. The housing thus differs from known enclosures, such as, e.g., metal sleeves, which are only pushed onto a piezo actuator, wherein individual piezo actuator regions, such as, e.g., an actuator foot, then protrude from the sleeve. Such sleeves are thus not a “hermetically” sealed housing in terms of the invention. It would generally also be possible that two or more piezo actuators are enclosed in a hermetically tight manner in the same housing. For example, two separately controllable piezo actuators could be arranged essentially parallel to one another in the same housing, wherein the housing interior space between the respective piezo actuators and the housing wall and/or between the two piezo actuators can then contain the potting compound. Without being limited thereto and unless mentioned otherwise, the invention will be described below on the basis of a housing with only one piezo actuator.

As mentioned above, the housing can be a deep-drawn housing. It should also be pointed out that in the case of all embodiments or further developments of the invention, respectively, a housing can be used, which can be obtained by means of deep-drawing. This means that, as part of the description, a “housing” is to in particular be understood to be a deep-drawn housing.

The housing comprises a potting compound, which is preferably introduced in free-flowing form into the housing in order to cure or harden in the housing, respectively. The potting compound can in particular be cast and/or injected into the housing. The potting compound can thus also be referred to as casting compound. The potting compound is preferably produced in the housing by introducing a free-flowing potting compound into the interior of the housing. The potting compound in the housing, in particular during operation of the actuator module, preferably forms a flexible solid body in the hardened state.

The potting compound in the hosing comprises at least one type of heat-conducting auxiliary substance. An inherent heat conductivity of the auxiliary substance, i.e., a heat conductivity of the auxiliary substance itself, can preferably be at least approximately 2.5 W/(m·K), preferably at least approximately 30 W/(m·K), preferably at least approximately 50 W/(m·K), more preferably at least approximately 100 W/(m·K), more preferably at least approximately 200 W/(m·K), particularly preferably at least approximately 300 W/(m·K), in particular at least approximately 400 W/(m·K). The above-mentioned values can preferably refer to the heat conductivity of an auxiliary substance, which is present in the form of a solid material block, e.g., a massive auxiliary substance block. As is customary, the heat conductivity or the heat conduction coefficient, respectively, is understood to be a substance property of the auxiliary substance, which determines the flow of heat through a material or the auxiliary substance, respectively, due to the heat conduction.

The heat-conducting, dielectric auxiliary substance preferably comprises a plurality of individual auxiliary substance particles or auxiliary substance particles, respectively, in particular prior to the introduction into the potting compound. The auxiliary substance particles can generally also agglomerate to form several particles and can optionally form a coherent structure. It is preferred, however, that the respective auxiliary substance particles are formed separately, in particular prior to the introduction into the potting compound. Without being limited thereto, it is assumed in the description of the invention that the used auxiliary substance comprises a plurality of auxiliary substance particles, wherein at least a majority of the auxiliary substance particles is formed separately, i.e., the auxiliary substance particles are preferably present in isolated form. The auxiliary substance can preferably inherently have a powder form, in particular prior to the introduction into the potting compound.

A powdery auxiliary substance, in particular outside of a potting compound, can preferably have an (inherent) heat conductivity of at least approximately 1 W/(m·K), preferably at least approximately 2 W/(m·K), preferably at least approximately 3 W/(m·K), more preferably at least approximately 4 W/(m·K), more preferably at least approximately 5 W/(m·K).

The auxiliary substance can preferably be formed in the form of platelets, also referred to as auxiliary substance platelets. The auxiliary substance in the potting compound can preferably be present in the form of platelets in the housing. A respective auxiliary substance particle in the housing can in particular have a predominantly platelet-like design. The auxiliary substance can preferably be an “anisotropic” filler and/or a filler with a large aspect ratio. An aspect ratio of an auxiliary substance particle can be, e.g., at least approximately 5:1, preferably at least approximately 25:1, preferably at least approximately 40:1.

A “platelet” is understood to be a flat element or particle, respectively, which has essentially the same thickness throughout and which is delimited on two opposite sides by a respective predominantly flat surface (base surface), which is comparatively expanded compared to a thickness. It should be pointed out that a respective auxiliary substance particle can also be designed only approximately as “platelet”. Such auxiliary substance particles, which have slightly different thicknesses within the same particle, are accordingly also referred to as “platelets”. The base surfaces can have different geometries, such as, e.g., approximately elliptical or circular shapes, wherein an outer contour of a base surface can also be formed irregularly. A “platelet-like” auxiliary substance particle, also referred to as auxiliary substance platelet, is accordingly defined in particular in that it has two predominantly flat base surfaces, wherein a thickness of the auxiliary substance particle (corresponds to the distance between the base surfaces) is several times smaller in relation to the expansion of the base surfaces.

The auxiliary substance can at least partially be arranged in the potting compound, in particular essentially all auxiliary substance particles, so that a longitudinal extension of a respective platelet or auxiliary substance platelet, respectively, runs transversely, preferably essentially orthogonally, to a longitudinal extension of the piezo actuator in the housing. The auxiliary substance particles, in particular essentially all auxiliary substance particles, can preferably be arranged in the potting compound so that a longitudinal extension of a respective auxiliary substance platelet corresponds to a shortest distance between a surface of the piezo actuator and the housing wall, in particular a defined heat output region of the housing.

The longitudinal extension (longitudinal expansion) of the piezo actuator is understood to be the largest or longest extension (expansion), respectively, of the piezo actuator in one direction. The longitudinal extension (longitudinal expansion) of an auxiliary substance platelet is understood to be the largest or longest extension (expansion), respectively, of the auxiliary substance platelet in one direction, in particular along at least one base surface of the auxiliary substance platelet.

A particularly efficient heat dissipation during operation can advantageously take place via the particular arrangement of the auxiliary substance platelets in the potting compound with respect to the piezo actuator. In the case of piezo actuators, a heat emission takes place largely in the lateral or radial direction, respectively, due to the layered construction during operation. This means that lost heat is output predominantly towards the side from a piezo actuator surface with regard to the longitudinal extension of the piezo actuator, wherein heat is hardly output in the axial direction, e.g., in the direction of an actuator foot or head, respectively. In the case of encapsulated piezo actuators, it is thus particularly effective when at least a majority of the lost heat can be fed laterally or radially away, respectively, from the piezo actuator via the auxiliary substance platelets in the potting compound, in particular because a lateral region of a piezo actuator accounts for a relatively large portion of an entire surface of the piezo actuator.

The auxiliary substance particles can advantageously be positioned in the potting compound, in particular also in direct vicinity to a surface of the piezo actuator (piezo actuator surface) and/or to the housing wall, so that the longitudinal extension of the individual auxiliary substance platelets essentially corresponds to a (main) heat output direction of the piezo actuator, which is at hand during operation. The auxiliary substance platelets can preferably be aligned unidirectionally in the potting compound and can be arranged so as to be distributed essentially evenly along the longitudinal extension of the piezo actuator. The developing lost heat can be dissipated particularly efficiently from the piezo actuator surface in the direction of the housing wall via the heat conducting auxiliary substance and the alignment thereof in the potting compound. In contrast, it is often the case in the case of known components with embedded auxiliary substances that the auxiliary substance particles can, for technical reasons, not be arranged in a certain orientation, which can have a disadvantageous effect on the thermal properties of the component.

Further advantageously, particularly efficient “heat conducting paths” can also be formed in the potting compound, in particular in an (entire) region between the piezo actuator surface and the housing wall, in particular between the piezo actuator surface and the housing jacket. In the description, that portion of a, preferably deep-drawn, housing, which extends at least along the longitudinal extension of the piezo actuator, in particular that portion, which extends along the piezo electrical material of the piezo actuator, is understood to be the housing jacket.

It can advantageously be attained via the nature of the auxiliary substance (platelet-shaped design) in combination with the alignment of the individual auxiliary substance particles in the potting compound (predominantly orthogonally to the longitudinal extension of the piezo actuator) that the individual auxiliary substance particles in the potting compound are in each case in active contact with at least one other auxiliary substance platelet via at least one contact point, if possible. Two auxiliary substance particles can preferably have a direct contact at a contact point.

The auxiliary substance platelets can in particular be arranged in the potting compound so that a, preferably interruption-free, connection or “bridge”, respectively, between two or more auxiliary substance particles is formed via the respective contact points. Such a bridge of auxiliary substance particles can preferably in each case be formed so that a heat conducting path for lost heat between the piezo actuator surface and the housing wall, in particular the housing jacket, is formed via this, preferably in an interruption-free manner. Particularly preferably, the auxiliary substance platelets can be arranged in the potting compound so that a plurality of bridges of this type of auxiliary substance particles (“auxiliary substance particle bridges”), is arranged in the potting compound, preferably predominantly in parallel. The bridges of auxiliary substance particles can preferably be arranged in the potting compound so as to be distributed essentially evenly along the longitudinal extension of the piezo actuator.

The heat dissipation from the piezo actuator can advantageously be further improved via such heat conducting paths. Due to the fact that, with regard to their longitudinal extension, preferably essentially all auxiliary substance platelets are arranged in the potting compound predominantly orthogonally to the longitudinal direction of the piezo actuator, the heat can be fed systematically from the piezo actuator to the housing jacket of the housing wall, wherein an unwanted, e.g., axial heat conduction in the potting compound can be prevented as far as possible. By means of the alignment of the auxiliary substance platelets, the lost heat can furthermore be fed on the most direct or shortest path possible, respectively, to the housing jacket via the bridge formation.

It is a further advantage that a comparatively large number of contact points can be formed between the auxiliary substance particles (which are present in the potting compound) via the auxiliary substance particles, which are designed in a platelet-like manner, and the alignment thereof in the potting compound, in particular compared to the same substance quantity of an isotropic, e.g., spherical auxiliary substance. Due to the fact that a missing (direct) contact between auxiliary substance particles can have a disadvantageous effect on the effectiveness of heat conduction paths, e.g., due to a potting compound, which does not conduct heat well, the heat quantity (per time unit) dissipated from the piezo actuator during operation can be increased further by means of the design of the auxiliary substance particles and the orientation thereof in the potting compound.

The auxiliary substance can preferably be boron nitride (BN). Particularly preferably, the auxiliary substance can be hexagonal boron nitride (α-boron nitride). Hexagonal boron nitride (α-Bn, hexagonal) consists of layers of a planar, hexagonal honeycomb structure, in the case of which the B- and N-atoms in each case appear alternately and is moreover well known. Particularly preferably, the boron nitride can be present as auxiliary substance prior to the processing in powder form with a pronounced crystal structure. Prior to the processing and/or in the hardened potting compound, the boron nitride can in particular be present in the form of platelet-shaped single crystals. Particularly preferably, a respective (BN) single crystal can in each case form an auxiliary substance particle or in each case an auxiliary substance platelet, respectively.

An average size of the platelets or auxiliary substance platelets, respectively, in particular an averaged diameter of the BN single crystals in the potting compound can be at least approximately 10 μm, preferably at least approximately 20 μm, preferably at least approximately 30 μm and/or maximally approximately 100 μm, preferably maximally approximately 80 μm, preferably maximally approximately 60 μm, in particular approximately 45 μm. The size or the diameter, respectively, of an auxiliary substance platelet is generally understood to be the longest extension of an auxiliary substance platelet in one direction, in particular provided that an auxiliary substance platelet has an irregular outer contour. An average particle size (D₅₀) in the potting compound can preferably be approximately 45 μm. For example, the auxiliary substance boron nitride can be of the type “CL-SP 045” (manufacturer: Henze Boron Nitride Products, AG, Germany).

Due to the particularly high heat conductivity of boron nitride (e.g., up to approximately 5 W (m·K) in the case of pulverized BN), the heat dissipation from the piezo actuator surface can advantageously be increased further. A further advantage of boron nitride compared to other heat-conducting substances is a high dielectric resistance as well as a low dielectric permittivity, so that boron nitride is suitable in particular in combination with encapsulated piezo actuators. Due to the fact that boron nitride in the α-modification has a low density (approx. 2.25 g·cm³) compared to other heat-conducting substances, the percentage by mass of boron nitride in the potting compound compared to other heat-conducting substances can be reduced, wherein a certain flow of heat can nonetheless be attained. The weight of the actuator module can thus be reduced, if required. The flow of heat is understood here as the heat energy, which is dissipated per time unit from the piezo actuator surface through the entire potting compound, i.e., a heat capacity.

The heat dissipation from the piezo actuator can further advantageously be increased via the particular shape and the size of the individual BN auxiliary substance particles because the number of the required contact points between the individual auxiliary substance particles for forming heat conducting paths can be reduced with increasing particle size, wherein each contact point forms a thermal resistance. In the case of BN auxiliary substance particles of a certain size, a particularly efficient heat dissipation is thus possible, wherein the BN auxiliary substance particles can nonetheless be arranged in the potting compound in the desired manner. A further advantage follows from the fact that hexagonal boron nitride has the property of a dry lubricant, wherein the coefficient of friction in the case of standard (surface) temperatures of piezo actuators remains stable. The piezo actuator can thus be stored in a sliding manner via the boron nitride in the potting compound.

The auxiliary substance, in particular hexagonal boron nitride, can preferably comprise a mixture of (auxiliary substance) particles, preferably platelets, with at least two different average sizes. The auxiliary substance can in particular comprise a mixture of powdery boron nitride with a first average particle size and powdery boron nitride with a second average particle size, which differs therefrom. The auxiliary substance, which is provided in the form of such a mixture, is also referred to as auxiliary substance mixture.

A mixture can preferably be provided in such a way that boron nitride powder with a (relatively) small average particle size is admixed to boron nitride powder with a (relatively) large average particle size. The auxiliary substance can preferably be a mixture of powdery boron nitride with an average particle size (D₅₀) of approximately 45 μm and of powdery boron nitride with an average particle size (D₅₀) of approximately 20 μm. Boron nitride of the type “CL-SP 045” and of the type “CL-ADM 020” can preferably be used for the mixture (manufacturer: Henze Boron Nitride Products AG, Germany). The powdery boron nitride with the average particle size of approximately 20 μm, e.g., type “CL-ADM 020”, preferably has an approximately platelet-like design.

Powdery boron nitride with an average particle size of approximately 20 μm can preferably be admixed to powdery boron nitride with an average particle size of approximately 45 μm, so that the (admixture) portion is at least approximately 1% by weight, based on the total quantity of the (ready mixed) auxiliary substance or of the auxiliary substance mixture, respectively. The (admixture) portion can preferably be at least approximately 2% by weight, preferably at least approximately 3% by weight, particularly preferably at least approximately 4% by weight. The (admixture) portion can preferably be approximately 4.25% by weight, in particular approximately 4.5% by weight.

Due to the use of boron nitride, which contains powder with different average particle sizes, the heat dissipation from the piezo actuator can advantageously be increased further. For example, the (relatively) small boron nitride particles can enter into intermediate spaces between the (relatively) large boron nitride particles and can fill them at least partially and/or can enlarge the contact surface of boron nitride with the housing.

In addition to the auxiliary substance, the potting compound in the housing preferably comprises a silicone gel, which comprises at least one base silicone and at least one crosslinking agent, in particular a hardener. Alternatively or additionally to the silicone gel, the potting compound in the housing could also comprise one or several polyurethanes. The potting compound could generally also be formed from other base components.

The potting compound in the housing is preferably formed so that, during operation of the actuator module for a certain period of use of the actuator module, it has at least one, preferably all of the following properties (simultaneously):
Essentially no separation of low-molecular reaction products, such as, e.g., H₂O, NH₃, CO₂, acetic acid, etc., from the potting compound takes place during operation.
An insulation resistance of the base components of the potting compound (without auxiliary substance), e.g., a silicone gel, is preferably at least 1·10¹² Ω·cm, preferably at least 1·10¹⁵ Ω·cm, in particular at least 1·10¹⁶ Ω·cm or more.
A (maximum) operating temperature of the potting compound is at least 140° C., preferably at least 160° C., preferably at least 200° C. or more.
For a certain period of use, the potting compound is stable against aging processes, in particular by preventing separations of conductive reaction products.
A heat conductivity of the base components of the potting compound (without auxiliary substance), e.g., a silicone gel, is preferably at least 0.08 W/(m·K), preferably at least 0.15 W/(m·K), in particular at least 0.2 W/(m·K).

The (hardened) potting compound in the housing, in particular due to the silicone gel, preferably has an average hardness (Shore A) of at least approximately 25, preferably at least approximately 35, preferably at least approximately 55 and/or an average hardness of maximally approximately 75, preferably of maximally approximately 65.

The potting compound in the housing is advantageously formed as solid body to be so (firm) that a certain alignment of the auxiliary substance particles in the potting compound is maintained during operation of the actuator module. However, the potting compound in the housing is also flexibly formed in order to provide for an expansion movement of the piezo actuator during operation and/or in order to provide for a (slight) deformation of the housing during operation. A further advantage of the potting compound with at least one silicone gel results during the production of the actuator module, wherein the potting compound can be introduced in free-flowing form into the housing via a small filling opening and then finally solidifies into the flexible solid body in the housing, as will be described later.

The potting compound can preferably be such that a portion of auxiliary substance, in particular hexagonal boron nitride, or a portion of an auxiliary substance mixture of the potting compound in the housing, respectively, in particular of the hardened potting compound, is at least approximately 50% by weight, preferably at least approximately 60% by weight, preferably at least approximately 65% by weight, in particular at least approximately 70% by weight.

The heat dissipation from the piezo actuator can advantageously be improved further via such a high percentage by mass of hexagonal boron nitride in the potting compound. In the case of a percentage by mass of α-boron nitride of 50% by weight and more, it can in particular be attained that a heat conductivity of the potting compound in the housing, i.e., by including the boron nitride, approaches a heat conductivity of the piezo actuator in the lateral direction, wherein a heat conductivity of the potting compound can essentially also correspond to a heat conductivity of the piezo actuator in the lateral direction.

The auxiliary substance, in particular boron nitride, can accordingly be arranged in the potting compound so that a heat conductivity of the hardened potting compound in the housing is at least approximately 90%, preferably at least approximately 95%, preferably at least approximately 99%, particularly preferably approximately 100%, in particular approximately 101% or more, of a heat conductivity of the piezo actuator, in particular of a heat conductivity of the piezo actuator in a lateral direction or in the direction of a shortest path to the housing wall, respectively. A lateral direction is understood to be a direction essentially transversely to the longitudinal extensions of the piezo actuator. For example, a lateral direction can run approximately parallel to the inner electrodes of a piezo actuator. A lateral region of a piezo actuator can preferably be a region of the piezo actuator between an actuator foot and an actuator head, in particular a section with inner electrodes stacked in layers.

For example, a heat conductivity of the piezo actuator surface in the lateral direction during operation of the actuator module, i.e. during operation of the piezo actuator, could be approximately 2.45 (W/(m·K). The potting compound can then preferably be formed, in particular with regard to the nature of boron nitride and/or the percentage by mass of boron nitride and/or the alignment of the BN single crystals in the potting compound, so that a heat conductivity of the final potting compound, in particular in a lateral direction from a piezo actuator surface to the housing wall or to the housing jacket, respectively, is at least approximately 2.45 W/(m·K) or slightly more. A further increase of the heat conductivity of the final potting compound, in particular in the lateral direction, can advantageously be attained by means of a mixture of boron nitride powders with different average particle sizes. For example, in the case of an admixture portion of approximately 1.5% by weight of boron nitride with an average particle size of 20 μm to 98.5% by weight of boron nitride with an average particle size of approximately 45 μm, a heat conductivity of the final potting compound of more than 3.5 W/(m·K) can be attained. The heat conductivity of the final potting compound can furthermore also be 4 W/(m·K) or more.

The lost heat developing during operation of the actuator module can thus advantageously be dissipated predominantly completely from the piezo actuator surface, so that the piezo actuator can be held in a certain temperature range. This can have advantages in particular in the case of jet valves with high clock frequencies because a risk of overheating of the piezo actuator is prevented and a continuous operation is thus possible.

For a particularly efficient heat dissipation, the housing interior space between the piezo actuator and the housing wall can be filled essentially completely with the hardened potting compound during operation. “Essentially completely” is to be understood such that a certain expansion volume can be present in the housing, in particular in order to compensate for a (necessary) thermal expansion of the piezo actuator and/or of the potting compound. Such an expansion region, which is free from potting compound, could comprise, e.g., a volume of an inert gas and/or can be formed as elongated hollow space, which runs essentially parallel to a longitudinal extension of the housing.

The housing, which hermetically encloses the piezo actuator, is preferably formed to be “permanently resistant to vibrations”. “Permanently resistant to vibrations” or “durable”, respectively, is understood here such that as part of a typical service life of the piezo actuator itself, which is arranged in the housing, i.e., after a number of vibrations (deflections), through which the piezo actuator can usually run during operation (due to the construction) regardless of the encapsulation, no signs of fatigue develop on the housing itself. The housing is preferably formed in order to form a sufficiently “permanent” and continuously effective hermetic diffusion barrier, so that no solids and/or no liquids and/or no gases can pass through the housing. The housing is preferably “permanently” formed so that it is completely intact, i.e., in particular forms a hermetic enclosure for the piezo actuator, even after a number of at least 2.5·10⁸, particularly preferably of at least 1·10⁹ cycles or deflections, respectively, of the encapsulated piezo actuator.

In order to attain a permanent resistance to vibration of the housing, the housing can be realized predominantly by means of a metallic material. Alternatively, individual regions of the housing can also be made of another, non-metallic, material. For example, a housing bottom and/or cover could comprise a ceramic base substance or could be realized by means of a flexible membrane. Different materials are also conceivable, as long as they provide for a sufficiently permanent hermetic sealing of the housing even during operation of the actuator module.

Particularly preferably, the housing can be produced by means of deep-drawing, as has been described above. The material of a deep-drawn housing base body can preferably be beryllium copper and/or stainless steel and/or steel. A housing cover can preferably be formed from beryllium copper and/or of stainless steel and/or of steel and/or of cooper and/or of brass. A housing cover can generally also be formed from at least one other metal or a metallic alloy. A wall thickness of a deep-drawn housing base body can be, e.g., at least approximately 0.05 mm, preferably at least approximately 0.08 mm. For example, a wall thickness of a deep-drawn housing base body can be approximately 0.09 mm, preferably approximately 0.1 mm. Larger wall thicknesses are generally also possible, e.g., 0.15 mm or more.

In order to form a deep-drawn, hermetically sealable housing, a housing base body and a housing cover could be soldered together. During the soldering, a temperature can preferably be less than 200° C., preferably less than 190° C., preferably less than 180° C. A lead solder and/or a tin solder and/or mixtures thereof can preferably be used as solder. The use of an eutectic solder is particularly advantageous.

For soldering purposes, the housing base body and/or the housing cover can preferably be coated with a solder. For example, a layer with a thickness of approximately 8 μm of a solder can be applied to an edge region of the housing cover, which is to be soldered and/or a portion of the housing base body, which receives the edge region, prior to the soldering.

For soldering purposes, a solder layer on the housing base body and/or on the housing cover can preferably be at least partially liquefied by means of induction. For soldering purposes, a frequency of an induction coil can preferably be at least 20 kHz, preferably at least 50 kHz, preferably at least 100 kHz. For example, a frequency can be maximally 500 kHz, preferably maximally 200 kHz, preferably maximally 150 kHz. However, higher frequencies, e.g., 600 KHz or more, can also be used for soldering purposes.

In particular by using the skin effect, a secure, in particular hermetically tight, connection can advantageously be formed between the housing base body and the housing cover, wherein a temperature in the housing can be kept as low as possible, in order to protect elements, such as, e.g., a piezo actuator, arranged therein. By using the skin effect, a temperature in the housing interior space and/or in the piezo actuator can advantageously be less than 200° C. due to a very short induction time, e.g., in the range of less than 500 milliseconds.

It would generally also be possible that a housing bottom, a housing jacket and a housing cover are (initially) produced as separate elements and are connected permanently and hermetically tightly to one another in order to form the housing, e.g., by means of welding, crimping, soldering, pressing, etc., wherein the three elements then form a housing wall. It would generally also be possible to initially provide two housing halves and to then connect them permanently and hermetically tightly, preferably along their longitudinal extension, in order to form a housing. It is preferred, however, that a housing is at least partially produced by means of deep-drawing, as has been described above.

Regardless of the concrete embodiment, a housing can preferably be formed, at least partially in the manner of a fold-like bellows, in particular of a fold-like metal bellows. In the case of a deep-drawn housing, for example, a bellows can be incorporated into the housing base body, in particular into the tubular housing jacket, at least in partial regions. Such a bellows can (after the deep-drawing) be introduced into the housing jacket, e.g., by means of hydroforming. A housing over, which is firmly connected to the housing jacket and which is preferably plane-parallel to the housing bottom, can form the upper closure of the housing. The housing base body and the housing cover then form the housing wall in this case.

Due to the at least partial design of the housing in the manner of a metallic bellows, it can advantageously be attained that the housing is partially formed to be resilient, wherein an expansion, which is as unhindered as possible, of the piezo actuator in the housing can take place when voltage is applied. A particular advantage follows in combination with a deep-drawn housing because the quick expansion of the piezo actuator is simplified additionally here by means of the small moved mass of the housing bottom.

The region of the housing with a bellows can preferably form a defined heat output region of the housing, via which a particularly efficient heat transfer from the housing wall (housing jacket) to the environment takes place during operation of the actuator module. For example, a cooling means of a higher-level machine, e.g., as part of a jet valve, could be assigned to the heat output region during operation, wherein the bellows then forms “cooling ribs”, around which a cooling medium preferably flows. The temperature of the piezo actuator can thus be set to a certain target value during operation of the actuator module and can in particular be actively regulated. The heat output region of the housing can preferably be assigned to the lateral region of a piezo actuator.

A housing can preferably be formed at least partially, in particular essentially completely, of one or several inorganic substances. A housing can preferably be constructed exclusively of inorganic materials in order to form a hermetically tightly sealed housing. A hermetically tight encapsulation of the piezo actuator can preferably (also) be attained in that only inorganic materials are used to encapsulate the piezo actuator, in particular to form the housing. The housing can, for example, be made of beryllium copper and/or stainless steel and/or steel and/or copper and/or brass and/or a different metal or a metallic alloy. The housing can accordingly be free from organic materials.

The housing is preferably formed in a hermetically tightly sealed manner so that a passage of substances, e.g., water molecules, through the housing, in particular by means of permeation is prevented or suppressed, respectively, during operation of the actuator module. A permeation during operation of the actuator module can preferably approach zero. In other words, the housing can form a permeation barrier or permeation block during operation, in particular for water molecules. During operation of the actuator module, the housing can preferably be formed to be permeation-tight. In order to prevent the permeation, the housing can accordingly be formed so that no substances (permeates) can penetrate or pass through the housing during operation.

A particularly reliable hermetic encapsulation of the piezo actuator and thus a permanent shielding of water molecules can advantageously be attained by means of a housing only of inorganic substances. In the case of other piezo actuators, which have a casing, which consists completely or predominantly of organic materials, e.g., on the basis of silicone, a passage of water molecules (permeation) through the organic material is possible during operation of the piezo actuator, in particular when a concentration gradient is present via the casing. The organic substances of such casings, e.g., silicone elastomers, often contain free water molecules in low concentration. Due to the fact that the water molecules are not bound in the organic substance, they can move until a concentration compensation has taken place between two sides of the organic substance, e.g., between an outer side and an inner side of a casing.

The hermetically sealed housing can advantageously be formed so that the piezo actuator in the housing can be electrically energized permanently (permanent energization) during a certain period of use of the actuator module. In the case of an electrical field applied permanently during operation, the piezo actuator can advantageously also be shielded effectively against water molecules of the external environment of the housing by means of the hermetically sealed housing. In the case of other piezo actuators with an organic casing, e.g., a silicone, water molecules can be transported through the casing and can be transported into the casing due to the electrical field developing as a result of the energization of the piezo actuator, in particular during a permanent energization.

The piezo actuator can preferably be arranged in the interior of the sealed housing so that the respective ends or end regions of the piezo actuator, respectively, rest directly on the housing base body or the housing bottom and cover, respectively, in particular when the piezo actuator is in a resting, thus non-expanded state. At least one end region of the piezo actuator, e.g., an actuator head, can preferably be firmly connected to the housing (cover).

The housing can preferably be designed so that a surface of the piezo actuator arranged in the housing and an inner side of the housing wall do not directly contact one another at least in the region of the housing jacket. In other words, an inner cross section of the housing, which runs essentially transversely to the longitudinal extension of the housing, can preferably be larger than a corresponding cross section of the piezo actuator arranged in the housing.

In order to monitor a temperature, at least one temperature sensor can be arranged on an inner side of the housing wall facing the piezo actuator and/or on an outer side of the housing wall lying opposite the inner side and/or within the potting compound. At least one temperature sensor, preferably two or more temperature sensors, can preferably be arranged in different regions of the piezo actuator surface in order to detect a temperature gradient along the longitudinal extension of the piezo actuator. At least one temperature sensor could also be arranged directly in a piezo actuator core, thus in a central center point of a transversely cut piezo actuator or in an (edge) region of a piezo actuator radially spaced apart therefrom.

The temperature sensors are preferably coupled to electrical terminals of the housing, which are fed through the housing wall in a hermetically tight and electrically insulated manner. Outside of the housing, the detected measuring values can be supplied, e.g., to a control means assigned to the actuator module. It should be pointed out that for the feedthrough through the housing wall, two or more electrical terminals can be combined at least temporarily so that several electrical terminals are fed through the housing wall via the same feedthrough. It is likewise possible, however, that a respective electrical terminal is fed separately through the housing wall.

The electrical terminals can preferably be realized by means of electrical plugs or terminal pins, respectively. The feedthrough of a respective plug through the housing preferably takes place by means of a respective glass solder, which is firmly integrated into the housing. The respective glass solders or glass feedthroughs, respectively, can preferably be integrated into the housing bottom (or the housing base body, respectively) and/or the housing cover. The electrical plugs or conductors, respectively, are particularly preferably fed to the outside from the interior of the housing in a hermetically tight and electrically insulated manner by means of glass solder.

In order to produce an actuator module, a potting compound is provided, as already described, which, the hardened state, preferably electrically insulates a housing wall from a piezo actuator. The potting compound itself, i.e., without the auxiliary substance, is preferably a dielectric. The potting compound is preferably arranged in the housing interior space so that essentially the entire piezo actuator surface is electrically insulated against the housing wall.

In a preferred method, a free-flowing potting compound is produced so that the potting compound to be introduced into the housing comprises a silicone gel, which comprises at least one base silicone and a crosslinking agent. The base silicone can be, e.g., a silicone of the type SG 75L2-30, wherein a type SG 79L5-30 can be used as crosslinker (respective manufacturer: Elantas, German). As already described, a polyurethane could also be used or a different suitable silicone, wherein the potting compound should preferably have the above-mentioned properties. Depending on the production method of the actuator module, a silicone gel with a higher viscosity than the above-mentioned silicone gel could also be used, for example.

In order to provide or produce, respectively, the free-flowing potting compound in a (first) step, a first half portion of the entire auxiliary substance to be used or of the entire auxiliary substance mixture, respectively, can preferably be mixed with at least a portion of a base silicone. A second half portion (of identical size) of the auxiliary substance or of the auxiliary substance mixture, respectively, is preferably mixed with at least a portion of the crosslinking agent. The first half portion of the auxiliary substance can preferably be mixed with a total quantity of the base silicone, which is provided in order to produce the potting compound. The second half portion of the auxiliary substance can accordingly be mixed with a total quantity of crosslinker.

In a further (second) step, the respective mixtures obtained in this way can preferably be mixed with one another in order to produce the free-flowing potting compound, which is to be introduced into the housing, via this.

The free-flowing potting compound can preferably be produced so that a respective portion of base silicone and/or of crosslinking agent of the potting compound prior to the introduction of the potting compound into the housing is at least approximately 10% by weight, preferably at least approximately 20% by weight, preferably at least approximately 25% by weight, in particular at least approximately 30% by weight or more.

The free-flowing potting compound can preferably be produced so that a portion of auxiliary substance, in particular of hexagonal boron nitride or a portion of the auxiliary substance mixture, respectively, of the potting compound, prior to the introduction of the potting compound into the housing, is at least approximately 10% by weight, preferably at least approximately 20% by weight, preferably at least approximately 25% by weight, particularly preferably at least approximately 30% by weight, in particular at least approximately 35% by weight. The potting compound is preferably produced so that the portion of the auxiliary substance or of the auxiliary substance mixture, respectively, of the (entire) free-flowing potting compound is maximally approximately 50% by weight, preferably maximally approximately 40% by weight. The auxiliary substance, in particular hexagonal boron nitride, in the form of platelets (auxiliary substance platelets) can preferably be arranged in the free-flowing potting compound.

Due to the fact that the auxiliary substance is divided into portions in order to produce the potting compound and is proportionately mixed with the individual components of the potting compound to be produced, a percentage by mass of auxiliary substance in the final, free-flowing potting compound can advantageously be set to be as high as possible. The percentage by mass of hexagonal boron nitride can in particular be increased compared to a method, in the case of which the same substance quantity (α-Bn) is mixed with only one component of the potting compound to be produced, wherein the potting compound is free-flowing or can be processed nonetheless, respectively. “Free-flowing” is understood to be a potting compound, which is such that the potting compound can be introduced into a housing by means of pressure and/or by means of an, in particular technically generated, inertia force in order to produce the actuator module, in particular via a filling opening of the housing. For example, a “free-flowing” potting compound can have a viscosity of maximally 1000 cSt (centistokes), preferably of maximally 500 cSt.

It can advantageously be attained by means of a free-flowing potting compound that the potting compound can be introduced into an otherwise already sealed housing via a very small filling opening, e.g., with a diameter of 1 mm or less. The potting compound can further advantageously be distributed in the housing interior space so that essentially the entire surface of the piezo actuator directly adjoins the hardened potting compound. The free-flowing potting compound in the housing can in particular flow around corners and can fill small hollow spaces.

According to one embodiment of the production method, the auxiliary substance or the auxiliary substance mixture, respectively, preferably hexagonal boron nitride, can be arranged in the form of platelets in the free-flowing potting compounds, in particular in order to align the auxiliary substance particles in the potting compound, wherein a pressure medium is applied to the potting compound, which has not yet hardened (in a still unsealed housing), for a certain time. A filling opening of the housing can in particular still be unsealed. The pressurization from outside the housing can preferably take place so that, as a result of the pressurization, a respective auxiliary substance platelet is arranged in the free-flowing and/or in the curing and/or in the hardened potting compound so that a longitudinal extension of a respective auxiliary substance platelet runs transversely, preferably essentially orthogonally, to a longitudinal extension of the piezo actuator.

A pressure can preferably be at least 100 bar, preferably at least 200 bar, particularly preferably at least 300 bar or more.

The pressurization can take place for at least one minute, preferably for at least 5 minutes, preferably for at least 10 minutes. The pressure medium can be a silicone oil. Alternatively or additionally, the pressure medium can be a dry gas and/or a dry gas mixture. The dry gas or gas mixture, respectively, preferably has a moisture content of maximally approximately 5 parts per million (ppm), preferably of maximally approximately 3 ppm, preferably of maximally approximately 2 ppm, particularly preferably of maximally approximately 1 ppm, in particular preferably of maximally approximately 0.5 ppm.

Alternatively or additionally, the potting compound in the housing can be subjected for a certain time to a pressure, which is reduced compared to normal pressure, in particular to a vacuum. A pulsed pressure load can preferably be carried out so that a positive pressure and a normal or negative pressure is alternately applied to the potting compound in the housing, in each case based on normal pressure.

A pulsed or repeated pressure load can advantageously contribute to the fact that essentially all auxiliary substance particles or auxiliary substance platelets, respectively, have a certain alignment in the hardened potting compound, in particular during operation of the piezo actuator.

According to one embodiment of the production method, the auxiliary substance or the auxiliary substance mixture, respectively, preferably hexagonal boron nitride, in the form of platelets can be arranged in the free-flowing potting compound, in particular in order to align the auxiliary substance particles, wherein the provision of the potting compound can take place as described above. In the case of this embodiment, the preferably not yet hardened potting compound can be subjected to a certain, in particular technically generated, inertia force in an unsealed or sealed housing. The free-flowing and/or the curing and/or the hardened potting compound can preferably be subjected to an, in particular technically generated, centrifugal force, so that, as a result of the centrifugal force, a respective auxiliary substance platelet is arranged in the free-flowing and/or in the curing and/or in the hardened potting compound so that a longitudinal extension of a respective auxiliary substance platelet runs transversely, preferably essentially orthogonally, to a longitudinal extension of the piezo actuator.

In the case of this embodiment, the auxiliary substance or the auxiliary substance mixture, respectively, in particular hexagonal boron nitride, in the form of platelets can particularly preferably be arranged in the free-flowing potting compound, wherein the potting compound is introduced into the housing itself by means of a certain, preferably technically generated inertia force, in particular a centrifugal force, which acts on the housing and/or on the potting compound. The inertia force is preferably applied so that the inertia force acts essentially orthogonally on the base surface of the respective auxiliary substance particles when introducing and/or when solidifying the potting compound, in particular based on a spatial arrangement or alignment, respectively, of the particles in the hardened potting compound.

A technically generated centrifugal force can in particular act on the housing and/or on the potting compound so that a respective auxiliary substance platelet, as a result of the centrifugal force with regard to the longitudinal extension thereof, is arranged transversely, preferably essentially orthogonally, to a longitudinal extension of the piezo actuator in the free-flowing and/or in the curing and/or in the hardened potting compound.

The method can preferably be carried out so that the inertia force acts on the potting compound, in particular on the auxiliary substance in the potting compound, essentially in the direction of a longitudinal extension of the housing, preferably in the direction of a longitudinal extension of the piezo actuator in the housing. The inertia force can preferably act on the potting compound and/or the auxiliary substance predominantly orthogonally to a shortest distance between the piezo actuator and the housing wall, in particular the housing jacket.

The potting compound with the auxiliary substance platelets can advantageously be introduced into the housing by means of an inertia force as well as a certain, advantageous alignment of the auxiliary substance platelets in the potting compounds can be attained. The production method can thus be carried out particularly efficiently and a certain alignment of essentially all auxiliary substance particles in the (hardened) potting compound can be attained. The inertia force can preferably be a technically generated centrifugal force.

It is a further advantage that in the case of the production method, the percentage by mass of the auxiliary substance, in particular hexagonal boron nitride, can be increased significantly in the hardened potting compound compared to other methods by using an inertia force aligned in a certain way to the housing. A portion of, e.g., up to 70% by weight of hexagonal boron nitride can preferably be attained in the hardened potting compound in the housing by means of the particular method, wherein the free-flowing potting compound has, e.g., only a portion of 35% by weight of hexagonal boron nitride. On the one hand, the percentage by mass of α-Bn can thus advantageously be set so that the potting compound is barely still free-flowing, wherein, on the other hand, the percentage by mass of α-BN in the hardened potting compound is significantly increased by means of the production method compared to the initial value. The heat conductivity of the potting compound can thus be increased in order to attain a particularly high heat dissipation from the piezo actuator.

It is generally possible that the two above-described embodiments are combined with one another. For example, a free-flowing potting compound can be introduced into a housing by means of a technically generated centrifugal force. The alignment of the auxiliary substance particles in the potting compound could then take place, e.g., by means of a pressurization of the potting compound in the housing. It would also be possible to introduce a free-flowing potting compound into a housing by means of centrifugal force, wherein a pressurization of the potting compound then takes place and wherein a centrifugal force is subsequently applied once again.

Regardless of the concrete embodiment, it can be provided in the production method that at least the housing and/or the piezo actuator and/or the auxiliary substance are subjected to a pretreatment prior to filling the potting compound into the housing. A pretreatment can preferably include that the components are subjected to a vacuum for a certain period of time and/or are heated to a certain temperature.

For heating and/or evacuation purposes, the housing can preferably comprise a deep-drawn housing base body and a housing cover, which is firmly connected thereto, wherein a piezo actuator is arranged in the housing and wherein the connection between the housing components is such that a hermetically tight seal of the housing can be formed (later) via this. The housing cover preferably has at least one sealable (filling) opening, which can be hermetically sealed tightly in order to form the final housing. Such a housing (with installed piezo actuator) as well as the auxiliary substance or the auxiliary substance mixture, respectively, is preferably subjected to a vacuum of, e.g., 10 to 100 mbar, in particular outside of the housing. A heating of the components preferably takes place simultaneously. The production method can accordingly preferably include a vacuum drying process. For the vacuum drying process, the components can be arranged in a heatable vacuum vessel, e.g., in a vacuum chamber.

A heating preferably takes place to a temperature of at least 60° C., preferably at least 90° C., preferably at least 110° C. and/or maximally 190° C., preferably maximally 150° C., preferably maximally 140° C. The heating and/or the evacuation can take place for at least 1 hour, preferably at least 2 hours, preferably at least 3 hours, particularly preferably at least 4 hours, in particular at least 5 hours, or more.

A heating of the components preferably takes place to a temperature of 130° C. for a duration of 48 hours. Particularly preferably, the components are arranged in a vacuum of approximately 10 mbar during the heating. Regardless of the concrete heating parameters, the heating can preferably take place by means of infrared radiation.

It can advantageously already be attained thereby that the housing interior space or the components, respectively, which are arranged in the interior of the hermetically sealed housing to be produced, are free from H₂O molecules as completely as possible.

During a heating and/or evacuation, in particular during a heating and/or evacuation in particular during a heating under vacuum, an electrical voltage can preferably be applied to the piezo actuator, at least once or briefly, respectively. In the vacuum drying process, electrical voltage can preferably be applied to the piezo actuator several times, in particular continuously during an entire duration of a heating under vacuum. The voltage can preferably be a voltage, which is maximally permissible for the piezo actuator. This approach can contribute to the fact that the components, which are to be dried or which are dried, respectively, in particular a piezo actuator in the housing, are freed from H₂O molecules particularly efficiently and reliably.

The vacuum drying process can preferably be carried out so that the vacuum vessel is flooded at least once with a protective gas. Protective gas can preferably be applied to the components to be dried for a certain period of time, in particular for a duration of approximately 30 seconds. A pressure of approximately 600 mbar can preferably be generated in the vacuum vessel during the flooding with protective gas. At the end of a protective gas application, an original vacuum can preferably be applied again. The protective gas can be a dry inert gas, e.g., dry argon.

The vacuum drying process can preferably be carried out so that the vacuum vessel is temporarily flooded twice or several times with protective gas. After a respective flooding with protective gas, a vacuum can preferably be applied again. Particularly preferably, the vacuum drying process can take place for a duration of 48 hours, whereby the vacuum vessel is flooded temporarily with a protective gas, in particular dry argon, at an interval of approximately two hours. A respective flooding duration can be approximately 30 seconds. By applying protective gas to the components and the subsequent evacuation, it can advantageously be attained that molecules, which are unwanted during operation of the piezo actuator (e.g., H₂O, H, O₂), can be removed particularly reliably from the components to be dried, in particular from an already partially sealed housing.

It can be provided in the production method that at least a portion of the piezo actuator, in particular at least a portion of the surface of the piezo actuator and/or at least a portion of the interior housing wall is cleaned by means of plasma cleaning. The plasma cleaning can preferably be carried out in a vacuum. The plasma cleaning can in particular be integrated into the described vacuum drying process. It would generally also be possible that a plasma cleaning takes place independently of the vacuum cleaning process. The plasma cleaning can then, for example, form a separate step of the production method. Regardless of the concrete embodiment, the plasma cleaning preferably takes place prior to filling the potting compound into the housing.

The plasma cleaning is preferably carried out on a housing with a piezo actuator arranged therein. The housing is preferably already partially sealed, wherein the housing interior space can be accessed from the outside via a sealable (filling) opening in the hosing cover. The piezo actuator can be adhered at least to the housing cover, preferably also to the opposite housing bottom. The plasma cleaning can preferably be carried out during the described vacuum drying process. During the vacuum drying, a plasma can preferably be generated once or repeatedly for a respective certain duration. It is also possible that a plasma is generated during the entire vacuum drying process. For the plasma cleaning, the housing with the piezo actuator can accordingly be arranged in the same vacuum vessel (as process chamber), in which the vacuum drying process is carried out, in particular simultaneously. The generation of a plasma can advantageously be promoted by means of a vacuum. The method can further advantageously be carried out more efficiently by means of this combination. Alternatively, the plasma cleaning could also be carried out on a housing, which was subjected to a vacuum drying process beforehand.

The method can be carried out so that the piezo actuator in housing forms an electric pole during the plasma cleaning. Electric current can preferably be applied to the two electrical terminals or connection poles, respectively, of the piezo actuator. The two electrical terminals of the piezo actuator can in particular be short-circuited during the plasma cleaning, in order to avoid a voltage potential in the piezo actuator. In order to generate an electrical field, a further electric pole can be formed through the housing, in particular through the deep-drawn housing base body. A plasma can then be generated between the housing and the piezo actuator surface. The housing can preferably form a ground connection. The two poles are preferably connected to a voltage source lying outside of the vacuum vessel.

The method can also be carried out so that a connection pole of the piezo actuator in each case forms an electric pole for generating the plasma. The plasma can then be generated locally (within certain limits) between the two connection poles of the piezo actuator. A combination of the two embodiments is also possible, in particular in the same vacuum drying process.

The plasma can preferably be generated by means of direct voltage, which is applied between the two electric poles (as electrodes). For example, a voltage of at least 100 volts can be applied, preferably at least approximately 200 volts.

The plasma can preferably be generated in argon or with argon, respectively. This has the advantage that the plasma cleaning can be integrated directly into the described vacuum drying process because argon is preferably used as protective gas therein. More advantageously, plasma can already form in argon starting at a voltage of approximately 100 volts. Alternatively, oxygen can be used for the plasma cleaning. This can be advantageous because oxygen has a comparatively strong cleaning effect.

Contaminations can advantageously be removed particularly effectively from the piezo actuator surface and/or from the inner side of the housing by means of such a plasma. Such soiling or contaminations, respectively, on the surface can be created in the production process, e.g., during the introduction of the piezo actuator into the housing and/or during the soldering of the housing cover and are often of organic origin. In particular the piezo actuator can be subjected to contaminations in a plurality of process steps, e.g., also by touching. These contaminations can have a disadvantageous effect on the operation of the encapsulated piezo actuator and can thus reduce the service life of the actuator module. A thorough and simultaneously efficient cleaning of the piezo actuator surface or of the interior housing wall, respectively, can advantageously be attained by means of plasma, wherein the removed contaminations or the components thereof, respectively, can be removed from the housing as gas.

The piezo actuator surface can advantageously be cleaned from contaminations by means of plasma in the region between the connection poles of the piezo actuator, in particular between the outer electrodes, can be cleansed. During operation, such contaminations can generate a leakage current or short-circuit between the positive and negative poles of the piezo actuator, which lie close together. The inner side of the housing bottom, the inner side of the housing jacket, preferably the inner side of the deep-drawn housing base body and the inner side of the housing cover, e.g., can furthermore be cleaned by means of plasma (at least in regions, which are not covered by the piezo actuator). Due to the fact that the piezo actuator is positioned in the housing as intended during the plasma cleaning, wherein the housing is already largely sealed, a later contamination of the piezo actuator and/or of the inner side of the housing wall can be avoided, if possible. Particular advantages can be attained in the case of a combination of the vacuum drying process with a simultaneous plasma cleaning. Contaminations can be at least largely evaporated by means of the plasma, so that they can be extracted from the housing as gas. Preferably, the vacuum can be raised routinely during the vacuum drying process by means of inflowing protective gas, preferably argon gas, for a certain period of time, e.g., several seconds, e.g., up to approximately 500 mbar, and can be lowered again subsequently. By means of the periodic flooding with protective gas and the subsequent lowering of the vacuum, gases and particles optionally contained therein, which result, e.g., from evaporated contaminations, can be removed from the housing, in particular be flushed out of it, through the unsealed (filling) opening in the housing.

The vacuum can preferably be eliminated after the drying process by means of heat and vacuum in such a keyboards. The fastening to, it can in particular be provided at the end of the plasma cleaning that a dry gas is applied to the dried components and/or to the piezo actuator cleaned by means of plasma or to the housing, respectively, or that they are flooded, which gas is preferably heavier than air, so that the gas enters, e.g., into the upright housing and remains therein, wherein an entry of air is prevented. The dry gas can preferably be argon, as will be described later.

In order to provide the potting compound by using the dried auxiliary substance, preferably dried hexagonal boron nitride in powder form, the further components or the base components of the potting compound, respectively, i.e., the base silicone and a crosslinker can be evacuated and/or dried prior to being brought together with the auxiliary substance, as has been explained previously, e.g., for the housing. The drying of the housing and of the auxiliary substance as well as of the base components of the potting compound could take place, for example, in a common method step, in particular in the same vacuum chamber and/or under the same parameters. A dry gas can preferably be applied to the dried (base) components of the potting compound by eliminating the vacuum, in particular in order to form a protective gas atmosphere with respect to the ambient air. It is pointed out that the evacuating and/or heating of the base components of the potting compound is an optional step and can be foregone, e.g., in the case of a production method, which is based on an inertia force.

A dry gas or gas mixture, in particular at least an inert gas, can preferably be applied to the housing and/or the piezo actuator and/or the auxiliary substance and/or the base components of the potting compound following the heating and/or evacuation, in particular to the housing with the piezo actuator following a plasma cleaning, preferably in order to form a protective gas atmosphere. The dry gas (mixture) of a protective gas atmosphere preferably has a residual moisture of maximally approximately 5 ppm, preferably of maximally approximately 3 ppm, preferably of maximally approximately 2 ppm, particularly preferably of maximally approximately 1 ppm, in particular preferably of maximally approximately 0.5 ppm. The dry gas preferably has a higher density than air, e.g., pure dry argon.

Regardless of the concrete embodiment of the method, a vacuum, in which the housing and/or the piezo actuator and/or the auxiliary substance and/or the (unmixed) base components of the potting compound are arranged, can particularly preferably be replaced directly with a protective gas atmosphere. The evacuation and/or the heating and/or the formation of a protective gas atmosphere can preferably take place in a vacuum chamber, which is to be opened in the direction against the gravity, wherein the dried components are arranged in a volume of the dry gas, in particular completely enclosed by it. The housing and/or the piezo actuator and/or the auxiliary substance and/or the base components of the potting compound are preferably also shielded against an ambient atmosphere via a dry gas of a high density (as protective gas atmosphere) even by eliminating the vacuum.

In spite of the elimination of the vacuum and a (still) unsealed housing, it can advantageously be ensured when using such a gas that no moisture can enter into the housing and/or into the auxiliary substance. The dry gas can in particular collect in the housing and can subsequently be displaced from the housing, e.g., by means of centrifugation due to entering potting compound, as will be described later. The use of argon with a residual moisture of less than 3 ppm has turned out to be advantageous because a sufficiently safe process environment can be attained therewith for the piezo actuator in the housing, wherein the acquisition costs compared to non-dried gas are moderate.

At the end of the drying process, the provision of the potting compound, in particular the mixing of the base components of the potting compound with the dried auxiliary substance, can preferably take place in such a (protective gas) atmosphere of a dried gas, e.g., argon with a residual moisture of less than 3 ppm. As has already been described, half of the auxiliary substance can preferably be mixed with a base silicone and a crosslinker, before the mixtures obtained in this way are brought together in order to produce the free-flowing potting compound. The potting compound finally produced in this way is preferably further processed immediately after bringing together the substances, in order to attain an alignment of the auxiliary substance platelets, which is as effective as possible, in the potting compound in the housing (regardless of the embodiment of the method).

For introduction into the housing—regardless of the embodiment of the method—the finally produced free-flowing potting compound preferably has a viscosity of at least approximately 100 cSt, preferably at least approximately 200 cSt, preferably at least approximately 300 cSt and/or maximally approximately 1000 cSt, preferably maximally approximately 750 cSt, preferably maximally approximately 500 cSt. A viscosity can generally also be higher. A free-flowing potting compound is preferably such that it can be introduced into the housing by means of a technically generated inertia force, preferably by means of centrifugation.

In the case of one embodiment of the method, the potting compound produced in this way can preferably be pushed or injected, respectively, into the housing with a pressure of at least 1 bar, preferably at least 2 bar, via the filling opening, wherein in particular an entry of (air) moisture into the housing and/or into the potting compound can be prevented during the introduction by storing the involved components in a protective atmosphere of dry gas.

The dry gas, e.g., argon, which is located in the housing prior to the filling, can advantageously be displaced from the housing when pushing in the potting compound, wherein essentially no air moisture can enter into the housing. In order to align the auxiliary substance platelets in the potting compound, a high pressure of, e.g., 300 bar, can subsequently be applied to the housing and/or the potting compound, as has already been described. The filling opening can subsequently be hermetically sealed by pressing in a ball.

It would alternatively also be possible that the provision of the potting compound, in particular the mixing of the base components with the auxiliary substance, takes place under vacuum, e.g., at a pressure of 10 mbar to 100 mbar. The production of the potting compound could in particular take place by continuously keeping the housing and/or the auxiliary substance and/or the piezo actuator and/or the base components of the potting compound in vacuum. It would also be possible that a produced free-flowing potting compound is evacuated (once again) prior to the introduction into the housing. A previously described approach can be advantageous, e.g., when the potting compound, as described, is introduced into the housing by means of pressure because an exit of the potting compound and/or of the gas contained therein from the filling opening of the housing as a result of a pressurization for aligning the auxiliary substance platelets can be prevented. In the case of this embodiment, it would also be possible, however, as mentioned, that the provision of the potting compound and/or the introduction of the potting compound into the housing takes place under a protective gas atmosphere (without vacuum), which makes the filling of the housing technically easier.

In the case of one embodiment of the method, the finally produced potting compound can be provided in a potting storage container. The potting compound can in particular be stored in the potting storage container so that it is shielded against an ambient atmosphere by means of a protective as atmosphere. In order to introduce the potting compound into the housing, the potting storage container or potting compound storage container can be coupled tightly with a filling opening of the housing. The potting storage container can in particular be coupled to the filling opening so as to form a seal, e.g., via an injection needle. It can advantageously be attained thereby that gas, e.g., argon, escapes from the housing through the injection needle during the filling and the potting compound drips into the potting storage container and thus reduces the viscosity of the potting compound in the storage container, optionally also in the housing, wherein the individual components of the potting compound are mixed in the storage container, optionally also in the housing mixed. It can further advantageously be attained thereby that after a complete filling of the housing with potting compound, the excess potting compound does not escape from the filling or loading opening, respectively, and contaminates, e.g., a centrifuge beaker. A housing interior space of the housing for introducing the potting compound is preferably filled essentially completely with a dry gas, in particular with a protective gas atmosphere.

An arrangement of the potting storage container and the housing, which is tightly coupled thereto, for introducing the potting compound into the housing can preferably be centrifuged. The centrifugation can in particular take place so that an axis of rotation runs essentially orthogonally to a longitudinal extension of the housing and/or of the piezo actuator in the housing. An introduction direction of the potting compound into the housing can in particular be essentially orthogonal to the axis of rotation and/or essentially parallel to a longitudinal extension of the housing.

The housing and/or the potting storage container coupled thereto can preferably be pivotably mounted for the centrifugation. The housing and the potting storage container coupled thereto can in particular be pivotably mounted so that a longitudinal extension of the housing and/or of the piezo actuator as a result of the centrifugation runs gradually, in particular when reaching a target acceleration, essentially transversely to the axis of rotation.

The centrifugation can be carried out, e.g., by means of a beaker centrifuge. The centrifugation preferably takes place for at least 30 seconds and/or maximally 60 seconds. The centrifugation preferably takes place with an acceleration of at least 8000 g and/or maximally 10000 g. In order to further increase the concentration of auxiliary substance in the potting compound in the housing, the centrifugation duration can be increased, e.g., and/or the acceleration can be increased.

The curing of the potting compound in the housing can take place at room temperature, preferably under a protective gas atmosphere. Alternatively, the curing can be accelerated at temperatures of up to 90° C. The opening can subsequently be hermetically sealed by pressing in a ball.

In the case of the method, it can advantageously be attained that a pretreated, e.g., evacuated and heated housing, optionally cleaned by means of plasma, with a piezo actuator therein, which is optionally cleaned by means of plasma, can be transferred into a centrifuge together with the volume located in the housing of a dry gas without special safety precautions, wherein the housing can be coupled first, e.g., to the potting storage container in the centrifuge, in particular under ambient atmosphere or without special conditions, respectively. A entry of air moisture (via the unsealed filling opening) into the housing, which is filled with a gas of a high density, can advantageously be prevented.

As a result of the centrifugation, the dry gas in the housing is further advantageously pushed out of the housing by means of the entering potting compound. This means that the gas volume can be exchanged directly with a corresponding volume of potting compound, so that no air moisture can reach into the interior of the housing. A hermetically tightly sealable housing with a piezo actuator arranged therein can thus be provided with comparatively simple technical means, wherein it is ensured by means of the production method that the interior of the hermetically sealed housing essentially does not contain any moisture. The piezo actuator is therefore also reliably protected against H₂O molecules. The provision of a potting compound, e.g., by mixing dried boron nitride and undried base silicone and crosslinker and/or the transfer of a free-flowing potting compound into a potting storage container can further advantageously also take place outside of a protective gas atmosphere, e.g., at ambient air.

In an optional step of the method, e.g., directional vibrations can be generated in the not yet cured potting compound, preferably in the auxiliary substance, in order to align the auxiliary substance in the potting compound. Directional vibrations with a certain frequency and/or amplitude can preferably be generated, e.g., by means of controlled shaking of the potting compound in the housing.

Alternatively or additionally, the not yet cured potting compound in the housing, in particular the auxiliary substance therein, can be arranged for a certain time in an outer electrical field and/or in an outer magnetic field in order to align the auxiliary substance.

Alternatively or additionally, the not yet cured potting compound in the housing, in particular the auxiliary substance therein, can be subjected to a temperature treatment with at least two different temperatures in order to align the auxiliary substance.

Alternatively or additionally, the method can be carried out so that a viscosity of the not yet cured potting compound in the housing is reduced by means of shearing compared to an untreated potting compound in order to align the auxiliary substance in the potting compound. A certain viscosity of the potting compound can preferably be attained, in particular by means of sound or ultrasound.

The above-described optional method steps can advantageously contribute to the fact that a certain alignment or arrangement, respectively, of the auxiliary substance in the potting compound is attained and/or accelerated. The method steps can be integrated into the production method individually or in a certain combination, also at different points in time. For example, a viscosity change of the potting compound can take place prior to a centrifugation, in order to intensify the centrifugation effect, wherein a pressure treatment of the potting compound can take place, e.g., after a centrifugation or between two centrifugation steps. It would generally be possible that the potting compound for carrying out one of these optional method steps is (not yet) arranged in the housing.

It can optionally be provided in the method that an auxiliary substance and at least one base component of a potting compound, e.g., a silicone gel, are introduced into the housing in a temporally offset manner, in particular sequentially. It is also possible that potting compound comprising a first fraction of an auxiliary substance is introduced into the housing first, wherein a second fraction of a (pure) auxiliary substance is introduced into the potting compound in the housing subsequently, e.g., step by step. A (final) potting compound can accordingly be generated in the housing, e.g., with a certain percentage of mass of an auxiliary substance.

In a potting storage container, for example, only one or several base components can initially be provided in order to form a free-flowing potting compound, e.g., a silicone gel. The silicone gel can be introduced into the housing by means of inertia force, e.g., by means of centrifugation. The housing can preferably be filled essentially completely with the silicone gel, wherein a partial filling is also possible. An auxiliary substance, preferably pulverized boron nitride, can then preferably be introduced into the (remaining) silicone gel in the storage container, wherein the auxiliary substance is transferred into the silicone gel in the housing by means of inertia force in order to form a potting compound. The auxiliary substance can preferably be introduced successively into the storage container and/or the housing.

A volume flow of the auxiliary substance into the housing can advantageously be controlled via a sequential introduction. A certain spatial distribution of the auxiliary substance in the potting compound can advantageously be generated via this, in particular a location-dependent density. It would also be possible, e.g., to generate at least two regions with a different density of the auxiliary substance and/or a density gradient in the potting compound.

The method can furthermore generally be carried out so that at least two different auxiliary substances, e.g., with different physical and/or chemical properties, and/or at least two different types of potting compounds are introduced into a housing, also sequentially.

The invention furthermore relates to an actuator module with at least the features of an actuator module according to the invention, wherein the actuator module can be obtained by means of an above-described production method.

The invention will be described once again in more detail below with reference to the enclosed figures on the basis of exemplary embodiments. Identical components in the different figures are thereby provided with identical reference numerals. The figures are generally not true-to-scale.

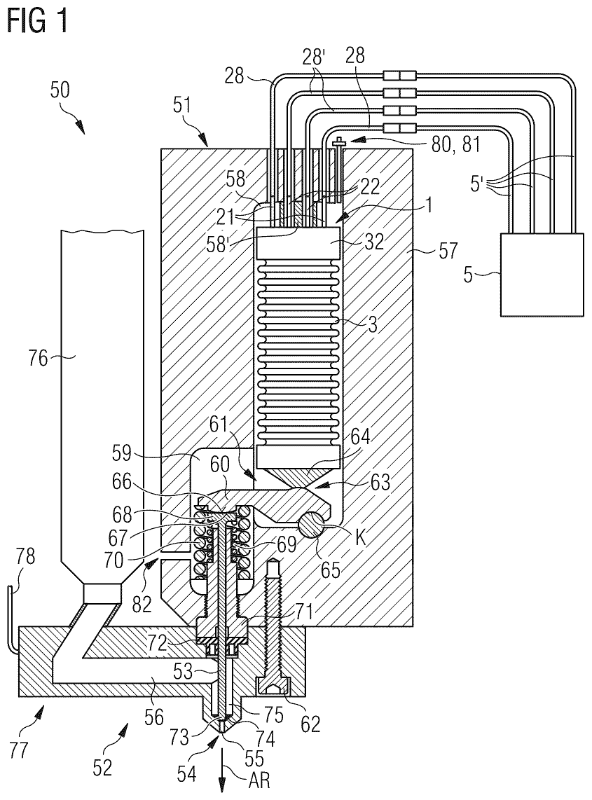

FIG. 1 shows a schematic sectional drawing through a metering system according to the invention,

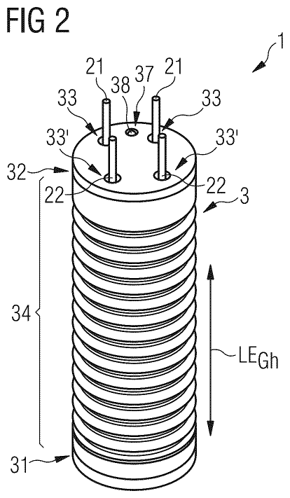

FIG. 2 shows a schematic, perspective view of an actuator module according to the invention,

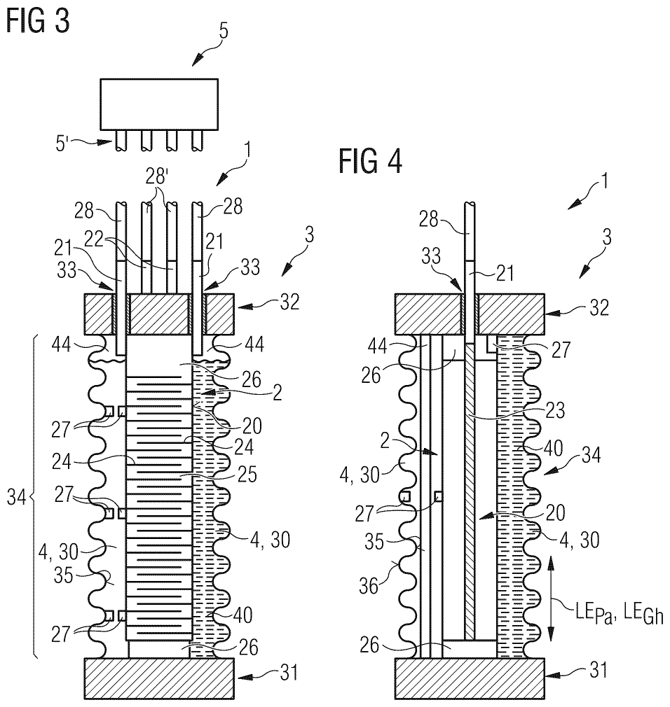

FIGS. 3 and 4 show schematic sectional drawings through actuator modules according to the invention,

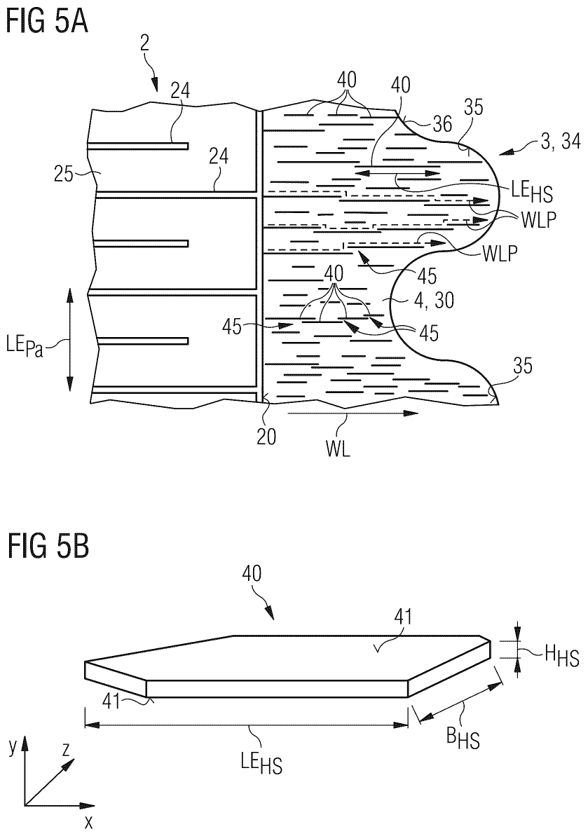

FIG. 5 shows a schematic and greatly enlarged view of a portion of an actuator module according to the invention and a schematic view of an auxiliary substance platelet,

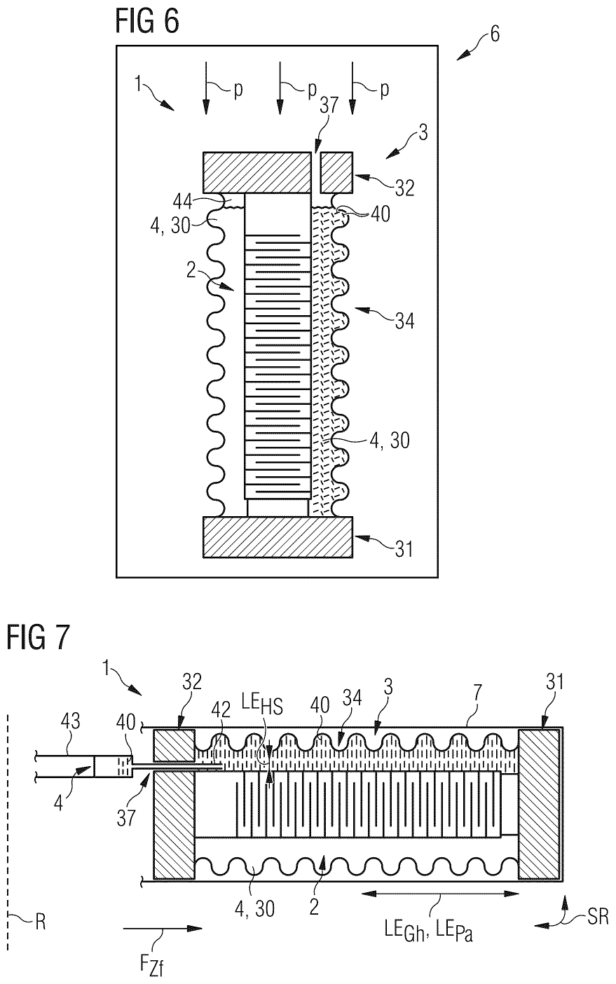

FIGS. 6 and 7 show schematic sectional drawings through actuator modules according to the invention.

The production of actuator modules according to the invention will be described below in an exemplary manner on the basis of a possible embodiment of a production method. For the sake of clarity, the method will be described on the basis of a single actuator module, wherein a plurality of actuator modules can be produced in parallel in the method.

In a first step, a hermetically sealable housing is provided, wherein the housing has at least one housing bottom and a housing jacket firmly connected thereto, preferably a deep-drawn housing base body. A (still unsealed) housing cover is provided, which has at least two electrical terminals for wiring a piezo actuator, e.g., two feedthroughs, which are hermetically tight and electrically insulated. A piezo actuator is firmly arranged on the housing cover, wherein a connection pole of the piezo actuator is in each case contacted by an electrical terminal, e.g., by means of soldering. The housing cover has at least one still unsealed filling opening for a potting compound, e.g., a circular hole with a diameter of approximately 1 mm.

In a further step, the piezo actuator is introduced into the housing, in particular into the housing base body, wherein the cover and the housing jacket are subsequently firmly connected to one another in order to form the housing, preferably by means of soldering or by means of welding, crimping, pressing or the like.

In a further step, the housing with the piezo actuator is transferred into a vacuum chamber. It would generally be possible to also carry out the introduction of the piezo actuator into the housing in a vacuum chamber. A defined quantity of hexagonal boron nitride, which is provided for the introduction into the respective housing, is subsequently provided in the vacuum chamber. The hexagonal boron nitride can be, e.g., a mixture of two boron nitride powders with a respective different average particle size.

The housing with the piezo actuator located therein as well as the boron nitride is subsequently heated to a temperature of 110° C. in a vacuum (10 mbar). The heating takes place by means of infrared radiation for a duration of, e.g., 5 hours. The housing with the piezo actuator located therein can optionally be subjected to a plasma cleaning during the vacuum drying.

After the evacuation and heating, the vacuum is eliminated, in that the vacuum chamber is filled or flooded, respectively, with an ultra-dry inert gas (residual moisture, e.g., <1 ppm). The inert gas forms a protective gas atmosphere in the (open) vacuum chamber, wherein the housing and the boron nitride are arranged, e.g., on the bottom of the vacuum chamber, so that the components are stored under a mirror made of dry gas.

In order to provide the potting compound, half of the boron nitride is in each case mixed with a base silicone and a crosslinker, before the mixtures obtained in this way are brought together for the production of the potting compound. The mixing can take place under ambient atmosphere or under protective gas atmosphere.

The potting compound is transferred into a potting compound storage container, optionally by shielding against an ambient atmosphere.

In order to fill a (single) housing, e.g., at least 1.6 g of hexagonal boron nitride, at least 0.85 g of (base) silicone and at least 1.3 g of a hardener or crosslinker, respectively, can be mixed. The provided volume of potting compound is predominantly a function of the volume of the housing interior space and is preferably calculated so that at the end of a centrifugation, a certain remainder of potting compound remains outside of the housing or in the potting storage container, respectively. It can thus advantageously be determined in a simple way that a largest possible volume of silicone gelt and/or boron nitride has been pressed into the housing by means of centrifugation and the housing is filled optimally.

A different ratio between boron nitride and base silicone or crosslinker, respectively, can more advantageously also be selected-within certain limits-because a largest possible concentration of boron nitride materializes automatically in the housing due to the particular production method by means of centrifugation and preferably as a function of the centrifugation parameters. In combination with a small excess of potting compound at the end of the centrifugation, it can be ensured in a simple way that the potting compound in the housing has a highest possible density of boron nitride.

In a further step, the housing is removed from the protective gas atmosphere and is immediately transferred into a beaker centrifuge, wherein the unsealed filling opening preferably points in a direction, which is opposite to the vertical direction, during the transfer and/or in the centrifuge, at least prior to the beginning of the centrifugation. The housing is advantageously filled essentially completely with the dry gas, which has a higher density than air, so that no ambient air enters into the housing during the transfer. The potting storage container is coupled tightly to the filling opening of the housing prior to the insertion into the centrifuge or in the centrifuge, respectively.

The arrangement of potting storage container and housing is subsequently centrifuged for at least 30 seconds with a (target) acceleration of 8000 g, wherein the arrangement is pivotably mounted. When reaching a target acceleration, a longitudinal extension of the housing and/or a longitudinal extension of the piezo actuator runs essentially orthogonally to the axis of rotation of the centrifuge.

Via the centrifugation, the potting compound is introduced into the housing on the one, wherein a preferred alignment of the boron nitride platelets with regard to the longitudinal extension of the piezo actuator takes place on the other hand. It can furthermore advantageously be attained by means of the centrifugation that predominantly the boron nitride enters into the housing, so that a percentage by mass of boron nitride can be increased in the hardened potting compound compared to an initial concentration in the free-flowing potting compound. It can further advantageously be attained by means of the centrifugation that the dry gas, which is present in the housing, is replaced directly by the same volume of the entering potting compound. It is ensured thereby that no moisture can enter into the housing during the production of the actuator module.

The volume of the free-flowing potting compound can be determined so that the entire housing interior space between the piezo actuator and the housing wall is filled by the hardened potting compound. A small volume of the housing interior space can optionally remain free from potting compound in order to form an expansion region. In order to form the expansion region, a thin small rod, e.g., in particular a thin small Teflon rod, can be pressed through the filling opening all the way onto the base of the housing after the filling with potting compound. After the curing of the potting compound, the small rod can be pulled out easily, wherein this preferably takes place under argon atmosphere and/or wherein argon or a different inert gas is filled into the formed hollow space after pulling out the small rod, e.g., via a needle, before the filling opening is hermetically sealed via the sealing ball. A hollow space, which extends essentially over the entire length of the housing, can advantageously be formed via this in the hardened potting compound, wherein a pressure increase from the inside is distributed as evenly as possible to an entire longitudinal extension of the housing during an expansion of the potting compound during operation.

The composition of the free-flowing potting compound and/or the centrifugation parameters are preferably selected so that the auxiliary substance particles are arranged so as to be distributed evenly along the entire longitudinal extension of the piezo actuator in the hardened potting compound. In other words, a concentration of auxiliary substance particles in different regions of the potting compound is preferably predominantly of equal size.

The curing of the potting compound in the housing can take place at room temperature or at temperatures of up to 90° C. The housing is subsequently hermetically sealed, optionally by inclusion of a small volume of dry gas. For this purpose, a steel or ceramic ball with a slightly larger diameter than the filling openings can be pressed into the filling opening at a high force (e.g., 600 N).

An actuator module produced in this way can be used, for example, in a metering system for metering liquid to viscous metering substances, e.g., in a jet valve, which is shown purely schematically and in section in FIG. 1. Due to the fact that the basic setup of jet valves of this type is known, only the essential elements will be described below.

As essential components, the metering system 50 comprises an actuator assembly 51 as well as a fluidic assembly 52, which is releasably coupled thereto, wherein the coupling takes place here in an exemplary manner via a screw 62. The actuator assembly 51 essentially comprises all components, which ensure the drive or the movement, respectively, of an ejection element 53 or of a tappet 53, respectively, of the fluidic assembly 52 in a nozzle 54.

In addition to the nozzle 54 and a supply channel 56 for metering substance to the nozzle 54, the fluidic assembly 52 comprises all further parts, which are directly in contact with the metering substance, as well as additionally the elements required to assemble the respective parts, which are in contact with the metering substance or metering medium, respectively, or to hold them in their position on the fluidic assembly 52, respectively.

In the exemplary embodiment of the metering system 50 shown here, the actuator assembly 51 comprises a housing block 57 with two internal chambers, namely on the one hand, an actuator chamber 58 with an actuator module 1 located therein with at least one piezoceramic actuator 2, which is hermetically encapsulated into a housing 3 (FIG. 3), and, on the other hand, an action chamber 59, into which a movable ejection element 53, here a tappet 53, of the fluidic assembly 52 protrudes. The tappet 53 is actuated via a lever 60, which protrudes from the actuator chamber 58 via an aperture 61 into the action chamber 59, so that the metering substance to be metered is ejected from the fluidic assembly 52 in the desired quantity at the desired point in time via the nozzle 54 in an ejection direction AR. The tappet 53 seals a nozzle opening 55 and thus also serves as sealing element 53. Due to the fact, however, that the largest portion of the medium is only ejected from the nozzle opening 54 by means of the tappet 53 when the tappet 53 moves towards the nozzle opening 55 in the ejection direction AR, it is referred to here as ejection element 53.

In order to control the piezo actuator 2 (FIG. 3), the actuator module 1 is connected electrically or in terms of signals, respectively, to a control means 5, which can also be formed, e.g., as part of the metering system 50. The connection to the control means 5 takes place via connection cables 5′, which are connected on the end side to actuator module control terminals 28, e.g., suitable plugs 28.

The actuator module control terminals 28 in each case contact an electrical terminal 21 in the housing 3, here two contact pins 21, which are each fed through a housing wall of the housing 3 in a hermetically tight and electrically insulated manner. In FIG. 1, the actuator module 1 comprises a total of four contact pins 21, 22, which are arranged in a housing cover 32. The two outer contact pins 21 here serve the purpose of controlling the piezo actuator or for the communication between piezo actuator and control means 5, respectively.

The two contact pins 22 shown centrally here are used in order to transfer measuring values from temperature sensors 27 (FIG. 3) from the housing 3 to the control means 5. For this purpose, the contact pins 22 are in each case connected on the one side to the control means 5 via temperature sensor terminals 28′ and on the other side to the individual temperature sensors 27 (not shown here) in the housing 3. For example, measuring values from several temperature sensors 27 could also be transferred to the control means 5 in a spatially resolved manner via the contact pins 22.

The piezo actuator 2 (FIG. 3) arranged in the housing 3—and via this also the housing 3—can expand and contract again in the longitudinal direction of the actuator chamber 58 according to a wiring by means of the control means 5. The actuator module 1 can be placed into the actuator chamber 58 from the top and can be mounted therein in a height-adjustable manner, wherein an exact adjustment of the actuator module 1 with regard to a movement mechanism 63 is made possible. In the case shown here, the housing cover 32 supports itself on the inside of the actuator chamber 58 via a support element 58′, wherein the support element 58′ serves as upper abutment here and can be adjusted, e.g., by means of a screwing movement (not shown) for an adjustment of the actuator module 1. The actuator module 1 is accordingly mounted here on the lever 60 via a pressure piece 64, which tapers downwards at an acute angle, which lever, in turn, rests on a lever bearing 65. The lever 60 can be tiled about a tilt axis K via this lever bearing 65, so that a lever arm of the lever 60 protrudes into the action chamber 59 through the aperture 61. On the end of the lever arm, the latter has a contact surface 66, which points in the direction of the tappet 53 of the fluidic assembly 52 coupled to the actuator assembly 51 and which pushes onto the contact surface 67 of the tappet head 68.

In the case of the shown exemplary embodiment, it is provided that the contact surface 66 of the lever 60 is permanently in contact with the contact surface 67 of the tappet head 68, in that a tappet spring 69 presses the tappet head 68 against the lever 60 from below. It would generally also be possible, however, that in an initial or rest position, respectively, of the tappet spring 69, a distance between tappet 53 and lever 60 is present. In order to provide for an almost constant pre-loading of the drive system, the lever 60 is pushed upwards here on the end, on which it comes into contact with the tappet 53, by means of an actuator spring 70.

The tappet 53 is supported by means of the tappet spring 69 on a tappet bearing 71, which is adjoined to the bottom by a tappet seal 72. The tappet spring 69 pushes the tappet head 68 upwards here, away from the tappet bearing 71 in the axial direction. A tappet tip 73 is thus also pushed away from a sealing seat 74 of the nozzle 54. This means that without external pressure from the top onto the tappet head 68, a nozzle opening 55 is also unsealed in the rest state (non-expanded state) of the piezo actuator 2 (FIG. 3).

The supply of the metering substance to the nozzle 54 takes place via a nozzle chamber 75 as well as an adjoining supply channel 56, which is connected to a metering substance reservoir 76. The fluidic assembly 52 comprises a frame part with a heating means 77, which is connected to the control means 5 by means of heating connection cables 78 and can additionally also have further components.

The metering system 50 comprises a controllable cooling means 80 here, which is shown in an exemplary and schematic manner. A cooling medium, e.g., compressed air or pre-cooled compressed air, can be introduced into the actuator chamber 58 via a cooling medium supply 81. The pressurized cooling medium flows through the actuator chamber 58 and can escape from the metering system 50 again via a cooling medium discharge 82. When passing through the actuator chamber 58, the cooling medium flows along an outer surface of the housing 3, wherein the heat developing during operation of the piezo actuator, which is fed via a potting compound with an auxiliary substance in the housing 3 (FIG. 4) all the way to the housing surface, can be dissipated via the cooling medium. By means of the cooperation of such a cooling means 80 with an actuator module 1 according to the invention, a particularly efficient heat dissipation from the piezo actuator can take place during operation of the metering system 50, which can have an advantageous effect on the metering precision and the service life of the piezo actuator.

A possible embodiment of an actuator module 1, which comprises a housing 3 and a hermetically encapsulated piezo actuator 2 (FIG. 3), is shown schematically and enlarged in FIG. 2. The housing 3 consists of a metallic material here and has a housing cover 32, a housing jacket 34 and a housing bottom 31, wherein the elements for forming the housing 3 are firmly connected to one another. Unlike shown here, the housing jacket 34 and the housing bottom 31 could also be formed integrally in the form of a deep-drawn housing base body 31, 34.

The housing jacket 34 is formed in the manner of a metallic bellows and has a number of regularly arranged horizontal elevations and depressions here. The longitudinal extension LE_{Gh} or longitudinal direction of the housing 3, respectively, corresponds to the longitudinal extension LE_{Pa} or longitudinal direction, respectively, of the piezo actuator 2 in the housing 3 (FIG. 4).

In FIG. 2, four separate electrical terminals 21, 22, here as contact pins 21, 22, are arranged in the housing cover 32. The respective contact pins 21, 22 are in each case fed from the outside via separate feedthroughs 33, 33′ through the housing cover 32 into the interior of the housing 3 in a hermetically tight and electrically insulated manner. The feedthroughs 33, 33′ are realized by means of glass solder here and can accordingly also be referred to as glass feedthroughs 33, 33′.

A filling opening 37 or loading opening 37, respectively, via which a free-flowing potting compound can be introduced into a housing interior space in the housing 3 in order to produce the actuator module 1, is furthermore arranged in the housing cover 32. The filling opening 37 is sealed here by means of a pressing ball 38, e.g., a metal ball 38 with a slightly larger diameter than an inner cross section of the filling opening 37, so that a housing interior space in the housing 3 is hermetically tightly sealed against a housing environment.

A housing interior space 30 of an actuator module 1 is shown, e.g., in FIG. 4 and refers to a space in the housing 3, which lies between the piezo actuator 2, in particular a piezo actuator surface 20, and an inner side 35 of the housing wall 31, 32, 34. The housing interior space 30 is filled essentially completely with a potting compound 4, wherein a small expansion region 44, e.g. a volume of a dry gas, is arranged in the housing interior space 30. Unlike shown in FIGS. 3 and 6, the expansion region 44 can preferably be a thin, elongated hollow space 44, which runs, e.g., in a direction LE_{Pa} or LE_{Gh}, respectively, in the potting compound 4, wherein the potting compound 4 then reaches from the housing bottom 31 all the way to the housing cover 32 (apart from the hollow space 44). Such an expansion region 44 is shown in an exemplary manner in FIG. 4. Due to the fact that the actuator modules 1 from FIGS. 3 and 4—apart from the expansion region 44—are constructed similarly and differ essentially in the view and the sectional plane, the actuator modules 1 are described together. Both actuator modules 1 from FIGS. 3 and 4 are illustrated in a greatly enlarged manner and purely schematically.

The actuator module 1 in FIG. 3 comprises a housing 3 with a housing cover 32, a housing jacket 34 and a housing bottom 31. Generally and unlike shown here, the actuator module 1 could also have a deep-drawn housing 3, wherein the housing jacket 34 and a housing bottom 31 would then be formed integrally. The remaining setup of the actuator module 1 or of the housing 3, respectively, could then be as in FIGS. 3 and 4.

Four electrical terminals 21, 22, which are each fed from the outside into the housing 3 in a hermetically tight and electrically insulated manner by means of a glass solder feedthrough 33 (only partially visible), are arranged in the housing cover 32. The contact pins 21, 22 are connected to actuator module control terminals 28 or temperature sensor terminals 28′, respectively, which terminals 28, 28′ are coupled to a control means 5.

The outer two contact pins 21 here each contact a connection pole of the piezo actuator 2 in the housing interior space 30. This becomes visible in particular in FIG. 4, wherein an electrical terminal 21 contacts an outer electrode 23 here as connection pole of the piezo actuator 2. The outer electrode 23 runs along a longitudinal extension LE_{Pa} of the piezo actuator 2 and, via this, connects the inner electrodes 24, which are fed to the corresponding side of the piezo actuator surface 20. The alternating arrangement of the inner electrodes 24 in the piezo actuator 2 is shown in the section in FIG. 3. The inner electrodes 24 are connected in parallel via the arrangement of two outer electrodes 23 on two opposite sides of the piezo actuator surface 20 (only one outer electrode 23 is visible in FIG. 4) and are combined to form two groups, wherein a wiring of the piezo actuator 2 can take place via the two electrical terminals 21 (FIG. 3).

The inner electrodes 24 are arranged between thin layers of a piezo-active material 25, wherein no piezo-active material 25 is arranged in the front-side regions 26 of the piezo actuator 2 or in the actuator head 26, respectively, and in the actuator foot 26, so that these regions can be referred to as inactive regions 26 (FIG. 3).

Several temperature sensors 27 are arranged on the piezo actuator surface 20 along the longitudinal extension LE_{Pa} of the piezo actuator 2. Temperature sensors 27 are furthermore arranged in different regions of an inner side 35 of the housing 3. The temperature sensors 27 are each connected to the two inner terminal pins 22 (FIG. 3) via terminals, which are not shown here, wherein a transfer of measuring values to the control means 5 takes place via the temperature sensor terminals 28′. These terminal pins are not shown in FIG. 4. Unlike shown in FIGS. 3 and 4, temperature sensors 27 could also be arranged on an outer side 36 of the housing 3.

In FIG. 3 as well as an in FIGS. 4 to 7, the potting compound 4 in the housing interior space 30 comprises hexagonal boron nitride 40 (α-BN, hexagonal) in powder form as auxiliary substance 40. For the sake of clarity, the auxiliary substance 40 in FIGS. 3 and 4 is in each case schematically arranged only in a portion of the housing interior space 30, which lies to the right of the piezo actuator 2, wherein in reality, the entire potting compound 4 in the housing 3 comprises the auxiliary substance 40. The auxiliary substance 40 is present in the form of auxiliary substance platelets 40 in the potting compound 4, wherein the individual auxiliary substance platelets 40 are aligned essentially unidirectionally, in particular with regard to the longitudinal extension LE_{Pa} of the piezo actuator 2. The auxiliary substance platelets 40 are arranged in the potting compound 4 so that an approximately even distribution of auxiliary substance platelets 40 along the longitudinal extension LE_{Pa} of the piezo actuator 2 results (FIG. 4).

The particular alignment of the individual auxiliary substance platelets 40 in the potting compound 4 is shown in FIG. 5A in a greatly enlarged and purely schematic manner in the cut-out of an actuator module according to the invention. The individual auxiliary substance platelets 40 are distributed essentially evenly along the longitudinal extension LE_{Pa} of the piezo actuator 2, wherein the respective auxiliary substance platelets 40 are aligned in the potting compound 4 so that a longitudinal extension LE_{HS} of the auxiliary substance platelets 40 runs essentially orthogonally to the longitudinal extension LE_{Pa} of the piezo actuator 2.

As is shown in FIG. 5B in an exemplary and purely schematic manner, the longitudinal extension LE_{HS} is defined as the longest extension of an auxiliary substance platelet 40 in a direction (here in the x-plane), wherein a maximum expansion of the auxiliary substance platelet 40 in the z-plane corresponds to a width Bus here. Due to the expansion of the auxiliary substance platelet 40 in the x- and the z-plane, two base surfaces 41 are formed, wherein a height Hus of the auxiliary substance platelet 40, which is orthogonal thereto, is comparatively small. In reality, an outer contour of the auxiliary substance platelets can be irregular, wherein, unlike shown here, the two base surfaces 41 also do not have to be exactly plane-parallel.

Auxiliary substance platelets 40 of this type are arranged in the potting compound 4 essentially unidirectionally so that essentially the same density of auxiliary substance platelets 40 is present in the potting compound 4 in all regions of the housing interior space 30, in particular in a region between the piezo actuator surface 20 and the inner side 35 of the housing 3. It is shown in the purely schematic illustration in FIG. 5A that a portion of the auxiliary substance platelets 40 directly adjoins the piezo actuator surface 20, e.g., is in direct contact therewith. This is advantageous on the one hand because, as dry lubricant, hexagonal boron nitride 40 (as auxiliary substance 40) provides for a sliding mounting of the piezo actuator 2 during operation. The developing lost heat can furthermore be dissipated particularly efficiently from the piezo actuator surface 20 via the direct contact. During operation, the heat output from the piezo actuator surface 20 typically takes place predominantly in a lateral direction, e.g., in a heat conduction direction WL.

The auxiliary substance platelets 40 are arranged unidirectionally and essentially orthogonally to the piezo actuator surface 20 so that at least a majority of the auxiliary substance platelets 40 in the potting compound 4 has contact to the respective at least one other auxiliary substance platelet 40 via contact points 45. As is shown in FIG. 5A, a coherent bridge of auxiliary substance platelets 40 can be formed via such contact points 45, namely as directly as possible from the piezo actuator surface 20, to as directly as possible to the inner side 35 of the housing 3. A heat conduction path WLP for lost heat can advantageously be formed along such a bridge. The direction of extension of a respective heat conduction path WLP corresponds essentially to the heat conduction direction WL of the piezo actuator 2 given during operation.

Due to the particular design and the alignment of the auxiliary substance platelets 40 in the potting compound 4, lost heat from the piezo actuator 2 can be dissipated systematically and by the shortest possible route to the inner side 35 of the housing 3, in particular to the housing jacket 34 during operation. Due to the shape and the alignment of the auxiliary substance platelets 40, the number of contact points 45 can furthermore be as small as possible, which improves the heat conductivity along the bridges of auxiliary substance platelets 40 or the efficiency of the heat conduction paths WLP, respectively. Unlike shown in FIG. 5A, a plurality of such heat conduction paths WLP will usually run through the potting compound, in particular so as to be distributed essentially evenly along the longitudinal extension LE_{Pa} of the piezo actuator 2.

An actuator module 1 is shown purely schematically and greatly enlarged in FIG. 6 in a production method according to the invention. The actuator module 1 comprises a housing 3 with a housing cover 32, a housing jacket 34 and a housing bottom 31, wherein the elements 32, 34, 31 are firmly connected to one another. Unlike shown here, the housing jacket 34 and the housing bottom 31 can also be formed by means of a deep-drawn housing 3.

A still unsealed filling opening 37 for potting compound 4 is arranged in the housing cover 32, wherein in the stage of the method shown here, the potting compound 4 is already arranged in the housing interior space 30. A portion of the housing interior space 30 does not contain any potting compound 4 and forms an expansion region 44 in the hardened state of the potting compound 4, wherein, unlike shown here, the expansion region 44 is preferably an elongated hollow space. The further components of the housing 3, e.g., the electrical terminals, are not shown here and can be realized similarly as in FIG. 3.

The housing 3 is located in a pressure chamber 6, wherein a dry gas or a silicone oil is arranged under high pressure p within the pressure chamber 6, e.g., pure dry argon with a pressure of approximately 300 bar. Unlike shown purely schematically here, the pressure p acts in the entire pressure chamber 6 and not only in the shown arrow direction. The high pressure p can act via the filling opening 37 on the potting compound 4 in the housing interior space 30 and in particular on the auxiliary substance platelets 40, which are located in the potting compound 4.

In FIG. 6, the individual auxiliary substance platelets 40 are not yet arranged unidirectionally, but rather randomly or chaotically, respectively, in the potting compound 4.

For the sake of clarity, the auxiliary substance platelets 40 are arranged schematically here (and in FIG. 7) only in a portion of the housing interior space 30, which lies to the right or above the piezo actuator 2, respectively, wherein, in reality, the entire potting compound 4 in the housing 3 comprises the auxiliary substance 40. In order to align the auxiliary substance platelets 40 essentially completely unidirectionally with their longitudinal extension transversely to the longitudinal extension of the piezo actuator 2, e.g., as shown in FIG. 5A, the gas, which is under the pressure p, or silicone oil can be applied to the unsealed housing 3, for example for a duration of 10 minutes. The filling opening 37 can subsequently be hermetically tightly sealed via a pressing ball 38 (FIG. 2).

An actuator module 1 is shown in a production method according to the invention in FIG. 7 in a purely schematic and greatly enlarged manner. The actuator module 1 comprises a housing 3, which is arranged in a centrifuge beaker 7 of a centrifuge, which is not shown in more detail, wherein the centrifuge beaker 7 is pivotably mounted according to a pivoting direction SR.

A potting compound 4 with auxiliary substance platelets 40 is already arranged in the housing interior space 30, wherein the individual auxiliary substance platelets 40 are already arranged predominantly unidirectionally. The housing cover 32 comprises a filling opening 37, to which a potting storage container 43 is currently coupled. The potting storage container 43 enters into the housing interior space 30 here via an injection needle 42. The injection needle 42 is sealingly arranged in the filling opening 37.

The further components of the housing cover 32 are not shown here and could be realized, e.g., similarly as in FIG. 3.

In FIG. 7, the entire housing interior space 30 is essentially already completely filled with potting compound 4. At the end of the centrifugation, potting compound 4 can preferably still remain in the potting storage container 43, which is shown schematically in FIG. 7.

For example, the percentage by mass of auxiliary substance platelets 40 in the potting compound 4 in the housing 3 can be increased thereby because the auxiliary substance platelets 40 preferably enter into the housing 3 as a result of the centrifugation, wherein the remaining potting compound 4, in particular the base components of the potting compound, such as, e.g., a silicone gel, then predominantly remains outside of the housing 3. For example, excess potting compound 4 can be arranged in a transparent potting storage container 43 in a visibly layered manner, in particular separated by boron nitride 40 (as auxiliary substance 40), which is optionally still present, and the silicone gel, wherein the boron nitride 40 is arranged predominantly in the region of the injection needle 42 and in the right portion of the potting storage container 43 here.

The method section shown in FIG. 7 shows a centrifugation with a target speed. In the region of the housing bottom 31, the centrifuge beaker 7 is pivoted open so far that a centrifugal force F_{Zt} acts essentially parallel to the longitudinal extension LE_{Gh} of the housing 3 or essentially parallel to the longitudinal extension LE_{Pa} of the piezo actuator 2, respectively. The centrifugal force Fa acts essentially orthogonally to the longitudinal extension LE_{HS} of the auxiliary substance platelets 40. The centrifugal force F_{Zt} in particular acts essentially orthogonally on a base surface 41 of the auxiliary substance platelets 40 (FIG. 5B).

The longitudinal extension LE_{HS} of the auxiliary substance platelets 40 is predominantly parallel to the axis of rotation R of the centrifuge here. The potting compound 4 can be introduced into the housing 3 by means of the method, which is described in FIG. 7 in an exemplary manner and in sections, wherein an alignment of the auxiliary substance platelets 40 takes place in the potting compound 4 in the same method, as described in more detail, e.g., in FIG. 5A.

At the end of the centrifugation, the injection needle 42 can preferably be removed from the housing 3, wherein an elongated small rod can then optionally be inserted into the filling opening 37 all the way to the housing bottom 31, in order to form an expansion region in the curing potting compound 4 via this.

In closing, it is pointed out once again that the actuator modules described in detail above are only exemplary embodiments, which can be modified in a large variety of ways by the person of skill in the art without leaving the scope of the invention. For example, a hermetically sealable housing produced by means of deep-drawing can thus be used in the respective exemplary embodiments. The use of the indefinite article “a” furthermore does not rule out that the respective features can also be present several times.

### LIST OF REFERENCE NUMERALS

1 actuator module
2 piezo actuator/component
3 housing
4 potting compound
5 control means
5′ connection cable
6 pressure chamber
7 centrifuge beaker
20 piezo actuator surface
21 contact pin (piezo actuator)
22 contact pin (temperature sensor)
23 outer electrode
24 inner electrode
25 piezo-active material
26 inactive region
27 temperature sensor
28 actuator module control terminals
28′ temperature sensor terminals
30 housing interior space
31 housing bottom
32 housing cover
33, 33′ feedthrough/glass feedthrough
34 housing jacket
35 inner side
36 outer side
37 filling opening/loading opening
38 pressing ball
40 auxiliary substance/auxiliary substance platelets/boron nitride
41 base surface
42 injection needle
43 potting storage container
44 expansion region
45 contact point
50 metering system
51 actuator assembly
52 fluidic assembly
53 ejection element/tappet
54 nozzle
55 nozzle opening
56 supply channel
57 housing block
58 actuator chamber
58′ support element
59 action chamber
60 lever
61 aperture
62 screw
63 movement mechanism
64 pressure piece
65 lever bearing
66 contact surface (lever)
67 contact surface (tappet head)
68 tappet head
69 tappet spring
70 actuator spring
71 tappet bearing
72 tappet seal
73 tappet tip
74 sealing seat
75 nozzle chamber
76 metering substance reservoir
77 heating means
78 heating connection cable
80 cooling means
81 cooling medium supply
82 cooling medium discharge
AR ejection direction
B_{HS} width auxiliary substance platelets
F_{Zf} centrifugal force
H_{HS} height auxiliary substance platelets
K tilt axis
LE_{Gh} longitudinal extension housing
LE_{HS} longitudinal extension auxiliary substance platelets
LE_{Pa} longitudinal extension piezo actuator
p pressure
R axis of rotation
SR pivot direction
WL heat conduction direction
WLP heat conduction path

1. An actuator module (1) with a hermetically sealed housing (3) with at least one piezo actuator (2) arranged in the housing (3) and with electrical terminals (21, 22) at least for the piezo actuator (2), which terminals (21, 22) are fed through a housing wall (31, 32, 34), wherein a housing interior space (30) between the piezo actuator (2) and the housing wall (31, 32, 34) includes a potting compound (4), which electrically insulates the housing wall (31, 32, 34) from the piezo actuator (2),
and wherein the potting compound (4) is a solid and comprises at least one particulate, heat-conducting, dielectric auxiliary substance (40), wherein the auxiliary substance (40) is arranged in the potting compound (4) so that a heat dissipation from the piezo actuator (2) to the housing wall (31, 32, 34) takes place during operation via the potting compound (4), in particular via the auxiliary substance (40).

2. The actuator module according to claim 1, wherein a heat conductivity of the auxiliary substance (40) is at least approximately 2.5 W/(m·K), preferably at least approximately 30 W/(m·K), preferably at least approximately 50 W/(m·K), more preferably at least approximately 100 W/(m·K), more preferably at least approximately 200 W/(m·K), particularly preferably at least approximately 300 W/(m·K), in particular at least approximately 400 W/(m·K).

3. The actuator module according to claim 1, wherein the auxiliary substance (40) is present in the form of platelets (40) in the potting compound (4) and/or wherein the auxiliary substance (40) is arranged at least partially, in particular essentially completely in the potting compound (4) so that a longitudinal extension (LE_{HS}) of a respective platelet (40) of the auxiliary substance (40) runs transversely, preferably essentially orthogonally, to a longitudinal extension (LE_{Pa}) of the piezo actuator (2).

4. The actuator module according to claim 1, wherein the auxiliary substance (40) is boron nitride (40), in particular hexagonal boron nitride (40), and/or wherein a size of a platelet (40) of the auxiliary substance (40) is at least approximately 10 μm, preferably at least approximately 20 μm, preferably at least approximately 30 μm and/or maximally approximately 100 μm, preferably maximally approximately 80 μm, preferably maximally approximately 60 μm, and/or wherein the auxiliary substance (40) comprises a mixture of particles, preferably platelets (40), with different average sizes.

5. The actuator module according to claim 1, wherein the potting compound (4) includes a silicone gel, which comprises at least one base silicone and at least one crosslinking agent.

6. The actuator module according to claim 1, wherein a portion of auxiliary substance (40), in particular hexagonal boron nitride (40), in the potting compound (4) in the housing (3) is at least approximately 50% by weight, preferably at least approximately 60% by weight, preferably at least approximately 65% by weight, in particular at least approximately 70% by weight.

7. A method for producing an actuator module (1) with a hermetically sealed housing (3) and at least one piezo actuator (2) arranged in the housing (3), in particular an actuator module (1) according to claim 1, with at least the following steps:
providing a hermetically sealable housing (3) with electrical terminals (21, 22) at least for one piezo actuator (2), wherein the terminals (21, 22) are fed through a housing wall (31, 32, 34),
introducing at least one piezo actuator (2) into a housing interior space (30) of the housing (3),
optionally cleaning at least a portion of the piezo actuator (2) and/or of at least a portion of an inner side (35) of the housing wall (31, 32, 34) by means of a plasma,
providing a potting compound (4), which, preferably in the hardened state, electrically insulates the housing wall (31, 32, 34) from the piezo actuator (2),
introducing the, preferably free-flowing, potting compound (4) into the housing interior space (30) between the piezo actuator (2) and the housing wall (31, 32, 34), preferably via a filling opening (37) in the housing (3), wherein the potting compound (4), in particular after a curing in the housing (3), is a solid and comprises at least one particulate, heat-conducting, dielectric auxiliary substance (40), wherein the auxiliary substance (40) is arranged in the potting compound (4) so that a heat dissipation from the piezo actuator (2) to the housing wall (31, 32, 34) takes place during operation via the potting compound (4), in particular via the auxiliary substance (40), and
hermetically sealing the housing (3).

8. The method according to claim 7, wherein a free-flowing potting compound (4) is provided so that the potting compound (4) to be introduced into the housing (3) comprises a silicone gel of at least one base silicone and a crosslinking agent and/or wherein, in order to provide a free-flowing potting compound (4), a first half portion of the auxiliary substance (40) is mixed with at least a portion of a base silicone and a second half portion of the auxiliary substance (40) is mixed with at least a portion of a crosslinking agent, wherein the mixtures obtained in this way are mixed with one another in order to produce the potting compound (4), which is to be introduced into the housing (3).

9. The method according to claim 7, wherein a free-flowing potting compound (4) is produced so that a respective portion of base silicone and/or of crosslinking agent in the potting compound (4) prior to an introduction of the potting compound (4) into the housing (3) is at least approximately 10% by weight, preferably at least approximately 20% by weight, preferably at least approximately 25% by weight, in particular at least approximately 30% by weight, and/or wherein a free-flowing potting compound (4) is produced so that a portion of auxiliary substance (40), in particular hexagonal boron nitride (40), in the potting compound (4) prior to an introduction of the potting compound (4) into the housing (3) is at least approximately 10% by weight, preferably at least approximately 20% by weight, preferably at least approximately 25% by weight, particularly preferably at least approximately 30% by weight, in particular at least approximately 35% by weight, and/or maximally approximately 50% by weight, preferably maximally approximately 40% by weight.

10. The method according to claim 7, wherein the auxiliary substance (40), in particular hexagonal boron nitride (40), in the form of platelets (40) is arranged in the free-flowing potting compound (4) and wherein a pressure medium is applied to the potting compound (4) in the housing (3) for a certain time, wherein a pressure (p) is preferably at least approximately 100 bar, preferably at least approximately 200 bar, particularly preferably at least approximately 300 bar or more.

11. The method according to claim 7, wherein the auxiliary substance (40), in particular hexagonal boron nitride (40), in the form of platelets (40) is arranged in the free-flowing potting compound (4) and wherein the potting compound (4) in the housing (3) is subjected to a certain inertia force (F_{Zf}), in particular a centrifugal force (F_{Zf}).

12. The method according to claim 7, wherein the auxiliary substance (40), in particular hexagonal boron nitride (40), in the form of platelets (40) is arranged in the free-flowing potting compound (4) and wherein the potting compound (4) is introduced into the housing (3) by means of a certain inertia force (F_{Zf}), in particular a centrifugal force (F_{Zf}), acting on the housing (3) and/or on the potting compound (4).

13. The method according to claim 11, wherein the inertia force (F_{Zf}) acts essentially in the direction of a longitudinal extension (LE_{Gh}) of the housing (3), preferably in the direction of a longitudinal extension (LE_{Pa}) of the piezo actuator (2), on the potting compound (4), in particular on the auxiliary substance (40) in the potting compound (4).

14. A metering system (50) for a metering substance with a nozzle (54) for outputting metering substance, a supply channel (56) for metering substance, an ejection element (53) and an actuator module (1) according to claim 1, which is coupled to the ejection element (53) and/or to the nozzle (54).

15. A hermetically sealed housing (3) with at least one component (2) arranged in the housing (3), preferably a piezo actuator (2), and with electrical terminals (21, 22) at least for the component (2), which terminals (21, 22) are fed through a housing wall (31, 32, 34), wherein the housing (3) has a housing base body (31, 34), which is formed in one piece, and a housing cover (32) and wherein the housing base body (31, 34) can be obtained by means of deep-drawing.

16. Use of an actuator module (1) according to claim 1 in a metering system (50) with at least one supply channel (56) for metering substance, a nozzle (54) for outputting metering substance and an ejection element (53), wherein the actuator module (1) cooperates with the ejection element (53) and/or the nozzle (54) during operation in order to output metering substance.
